(19) United States
(12) Patent Application Publication
(10) Pub. No.: US 2014/0019072 A1
(43) Pub. Date: Jan. 16, 2014

(54) PREPROCESSOR FOR REMOVING MASKING SIGNALS IN A TIME TRACE DISAGGREGATION PROCESS

(71) Applicant: Harold Gene Alles, Lake Oswego, OR (US)

(72) Inventor: Harold Gene Alles, Lake Oswego, OR (US)

(73) Assignee: VERLITICS, INC., Portland, OR (US)

(21) Appl. No.: 13/550,474

(22) Filed: Jul. 16, 2012

(51) Int. Cl. G06F 19/00; G01R 21/00

(52) U.S. Cl. 702/60

(57) ABSTRACT

A method can include receiving raw data having power samples that correspond to various types of electrical devices. A cycle detector can process the power samples to detect a masking data cycle and determine masking parameters that characterize the masking data cycle. The power samples can be stored in a circular data buffer, and the masking parameters can be stored in a circular cycle parameter buffer. A cycle characterization can determine whether there is masking data within the raw data and, if there is, call a removal process to remove the masking data.

### TECHNICAL FIELD

This disclosure relates generally to time trace disaggregation processes, and more particularly to operations for removing masking signals therefrom.

### BACKGROUND

Previous processes for identifying multiple individual loads supplied by a common AC power service use measurements of electrical parameters of only the common supply. These parameters are digitally measured for each alternating current (AC) supply cycle, e.g., 60 samples per second in North America. The loads are identified using the time dependent behaviors (referred to herein as time traces) of the first few seconds of the turn-on positive transition of these parameters. Many conventional devices such as incandescent lights and heaters consume essentially constant power after the positive transition until the device is turned off, thus producing a negative transition. Provided none of the transitions occur too close together, the on-off state of multiple devices can be accurately determined, as well as the power, runtime, and energy consumed by each device.

However, there are many devices today that use a continuously variable amount of power while turned on. These variations cause the measured electrical parameters of the common supply to also vary and, therefore, interfere with the process of identifying positive and negative transitions of conventional devices. These variable loads mask the identity of conventional devices, and significantly reduce the accuracy of the time trace disaggregation process. Masking data of concern consumes a minimum and maximum power (referred to herein as a masking cycle) at least every second, and as many as 30 masking cycles per second, e.g., the maximum possible with 60 samples per second. Peak-to-peak variations of 10 watts reduce the identification accuracy of conventional devices that consume less than 50 watts. Indeed, some masking data exceed 1000 watts, thereby affecting the identification and tracking of essentially all conventional devices in a residential building.

### BRIEF DESCRIPTION OF THE DRAWINGS

FIG. 1 is a graph of power positive transitions of six conventional devices: a capacitor start motor, incandescent light, heater, refrigerator, microwave oven, and fluorescent light.

FIG. 2 is a graph of masking data produced by a chaotic type device.

FIG. 3 is a graph of masking data produced by a periodic type device.

FIG. 4 is a graph of masking data produced by a rectangular type device.

FIG. 5 is a graph of masking data produced by a pulse type device.

FIG. 6 is a flow diagram of a preprocessing process and data flow in accordance with certain embodiments of the disclosed technology.

FIG. 7 is graph illustrating the samples of chaotic type power cycles and the thresholds used to detect a masking data cycle in accordance with certain embodiments of the disclosed technology.

FIG. 8 is a flow diagram of a process used by the CYCLE CHARACTERIZATION process to determine when masking data is present in accordance with certain embodiments of the disclosed technology.

FIGS. 9A and 9B together constitute a flow diagram of a CHARACTERIZE MASKING DATA process within the CYCLE CHARACTERIZATION of FIG. 6 to determine the type of masking data present in accordance with certain embodiments of the disclosed technology.

FIGS. 10A and 10B together constitute a flow diagram of a TRANSITION DETECTOR process, such as the TRANSITION DETECTOR of FIG. 6, in accordance with certain embodiments of the disclosed technology.

FIG. 11 is a flow diagram of a CHAOTIC REMOVAL process, such as may be called by the CYCLE CHARACTERIZATION of FIG. 6, in accordance with certain embodiments of the disclosed technology.

FIG. 12 is an overlay graph of power samples illustrating the typical results of a CHAOTIC REMOVAL process, such as the CHAOTIC REMOVAL process of FIG. 11, in accordance with certain embodiments of the disclosed technology.

FIGS. 13A and 13B together constitute a flow diagram of a PERIODIC REMOVAL process, such as may be called by the CYCLE CHARACTERIZATION 612 of FIG. 6, in accordance with certain embodiments of the disclosed technology.

FIG. 14 is an overlay graph of power samples illustrating typical results of the PERIODIC REMOVAL process of FIG. 13, in accordance with certain embodiments of the disclosed technology.

FIGS. 15A and 15B together constitute a flow diagram of a RECTANGULAR REMOVAL process, such as may be called by the CYCLE CHARACTERIZATION of FIG. 6, in accordance with certain embodiments of the disclosed technology.

FIG. 16 is a graph of the power samples of a decreasing portion of a conventional positive transition combined with one rectangular masking data cycle in accordance with certain embodiments of the disclosed technology.

FIGS. 17A and 17B together constitute a flow diagram of a PULSE REMOVAL process, such as may be called by the CYCLE CHARACTERIZATION of FIG. 6, in accordance with certain embodiments of the disclosed technology.

FIG. 18 is a graph of the power samples of a decreasing portion of a conventional positive transition combined with one pulse masking data cycle in accordance with certain embodiments of the disclosed technology.

FIG. 19 is a graph of the power samples of a step portion of a conventional positive transition combined with one pulse masking data cycle in accordance with certain embodiments of the disclosed technology.

FIG. 20 is a graph of the power samples of a peak portion of a conventional positive transition combined with one pulse masking data cycle in accordance with certain embodiments of the disclosed technology.

### DETAILED DESCRIPTION

Embodiments of the disclosed technology generally include the removing of masking data caused by variable load devices from the total data such that conventional devices can be identified and tracked using a time trace disaggregation process.

Certain embodiments further include identifying the masking device(s) and determining the power, runtime, and energy consumed by each masking device.

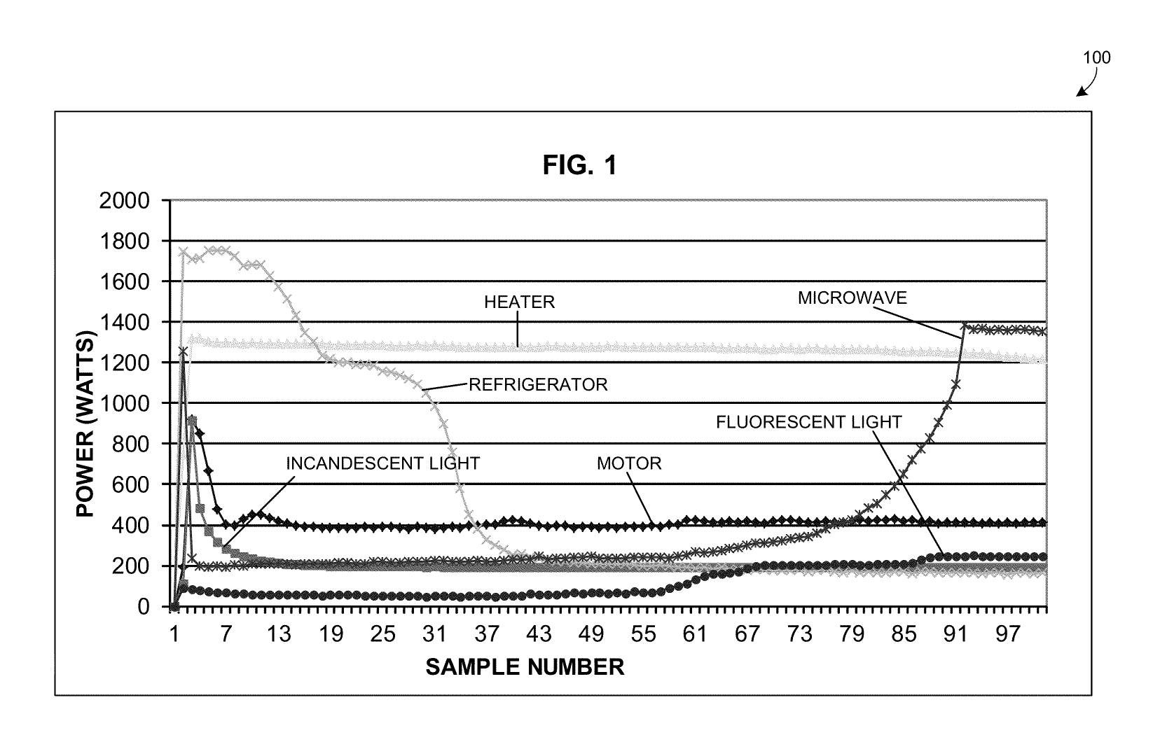

FIG. 1 is a graph 100 of power positive transitions of six conventional devices: a capacitor start motor, incandescent light, heater, refrigerator, microwave oven, and fluorescent light. The shapes of these positive transitions enable the time trace disaggregation process to identify the type of device that turned on. The horizontal axis represents the number of samples at 60 samples per second and has a total range of approximately 1.67 seconds. The devices in this example are as follows:

1. Capacitor-start motor used in a dish washer

2. Incandescent light (two 100 watt lights wired in parallel)

3. Electric oven heater (1300 watt)

4. Residential refrigerator

5. Household microwave oven

6. Fluorescent light (six 40 watt tubes wired in parallel)

Masking data can obscure these traces, e.g., by introducing features that are not in the conventional positive transitions or preventing key features from being recognized.

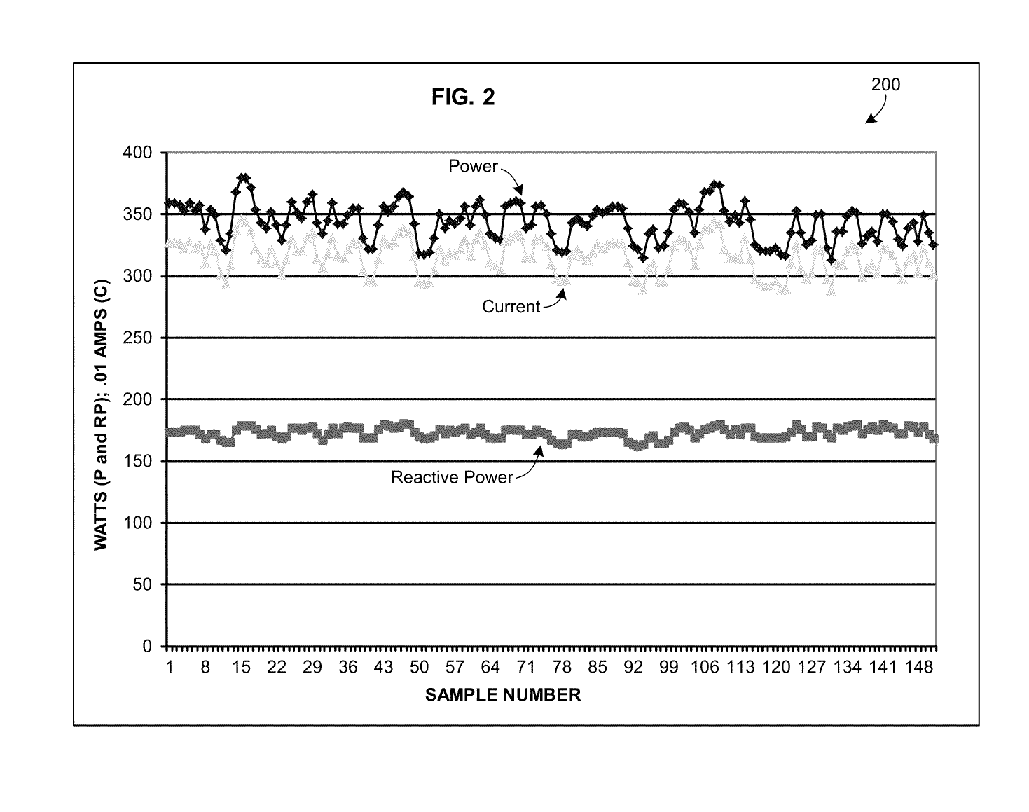

At least four distinct types of masking data may be found in typical residential and light commercial buildings. These are illustrated in FIGS. 2 through 5. The graphs 200-500, respectively, in these figures represent samples of power, reactive power, and current. Only the peak-to-peak variation is caused by the masking data; the fixed offset values are caused by other conventional devices.

FIG. 2 is a graph 200 of masking data produced by a chaotic type device. Chaotic type masking data is typically produced by computers, digital video recorders and players, cable boxes, large screen televisions and other electronically controlled devices. A switching power supply generally responds to the demands of disk drives, processors, and/or picture illumination. The masking cycle period, the peak-to-peak variation, and the shape of each cycle are highly variable. Typical masking data cycle peak-to-peak power is less than 100 watts for these devices.

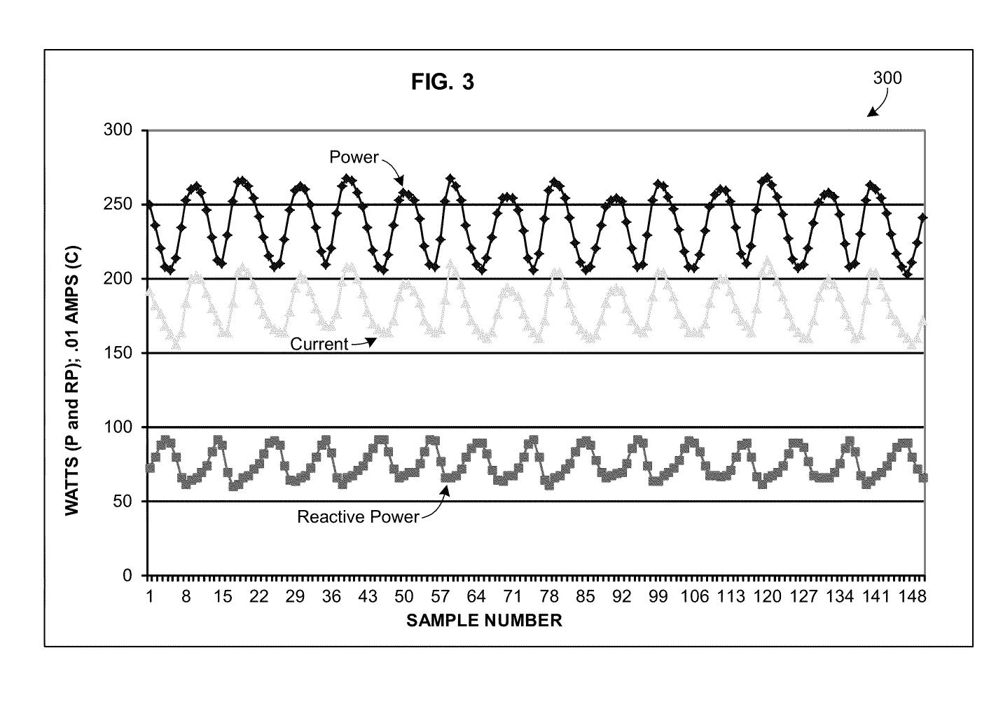

FIG. 3 is a graph 300 of masking data produced by a periodic type device. Periodic masking data is typically produced by motors driving rotating equipment (such as a piston type air compressor) and certain types of electronically controlled devices. The masking data cycle period and peak-to-peak variation are very small. The shape of each cycle or adjacent pair of cycles is nearly identical and typically varies smoothly, e.g., similar to a sine curve. Masking data cycle peak-to-peak power is typically less than 1000 watts for these devices.

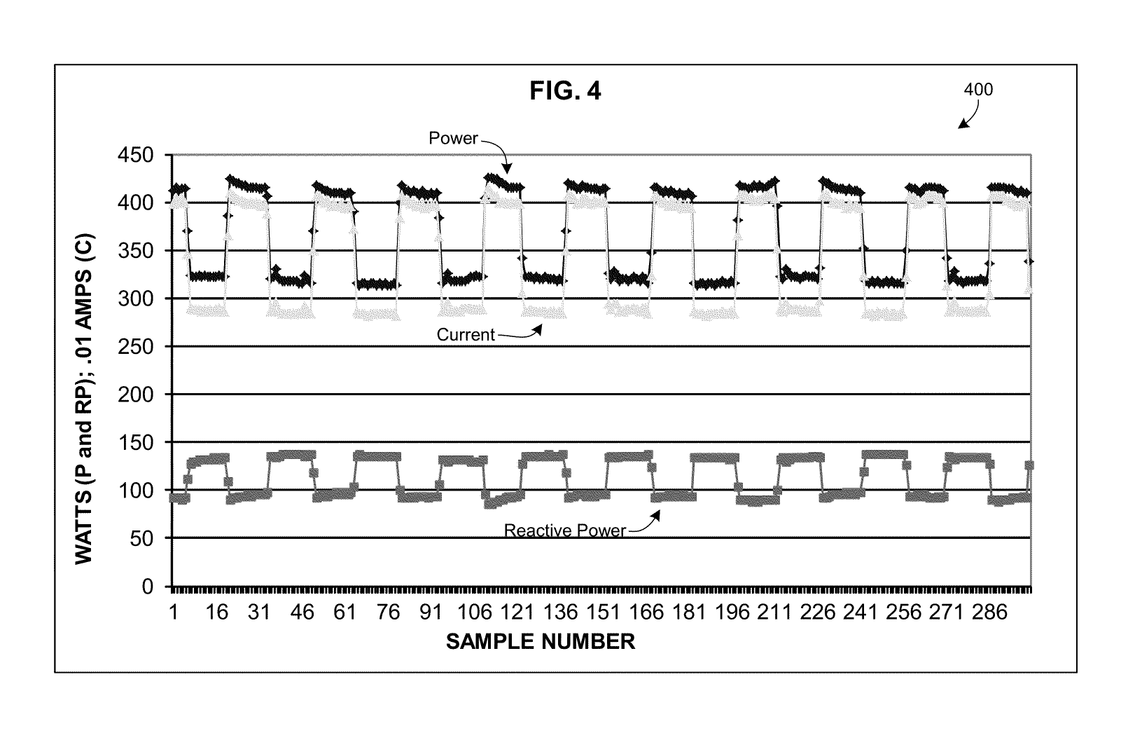

FIG. 4 is a graph 400 of masking data produced by a rectangular type device. Rectangular masking data is typically produced by battery chargers and other power pulse width modulated (PWM) control processes. The masking data cycle period and peak-to-peak variation are very small. The masking data cycle shape is rectangular with the transitions between minimum and maximum values occurring within two AC cycles. Another characteristic is that at least two samples of each masking data cycle must be stable and near the minimum value and at least two samples of each masking data cycle must be stable and near the maximum value. Masking data cycle peak-to-peak power can exceed 1000 watts. For example, some electric clothes dryers can produce 1500 watt masking cycles with a period of about 0.7 seconds.

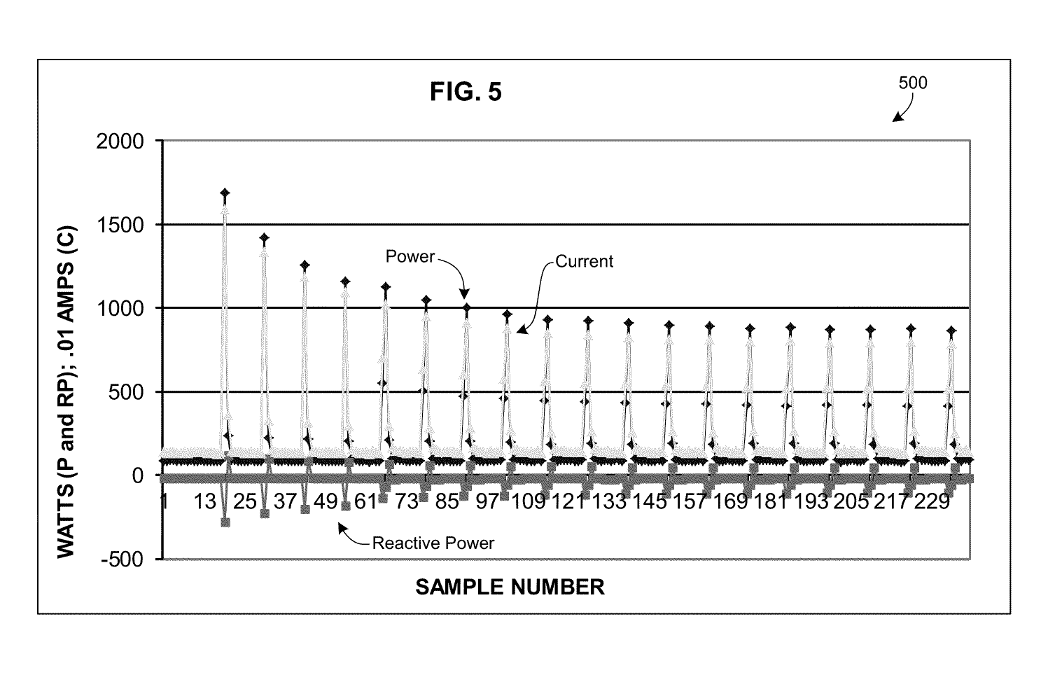

FIG. 5 is a graph 500 of masking data produced by a pulse type device. Pulse masking data is typically produced by office grade printers and certain electronically controlled devices. The pulses are usually positive, but may also be negative. A pulse is one to three samples wide and the peak-to-peak value may vary significantly. The masking cycle period variation is very small. The masking data cycles may be synchronized with the A/C cycles so that a pulse may be as little as a portion of a single A/C cycle. These pulses may be spaced a fixed number of AC cycles apart. A silicon-controlled rectifier (SCR) type control is often used to control the power used during the pulse. Masking data cycle peak-to-peak power may exceed 1000 watts for these devices.

Some masking devices produce masking data that changes from one type to another. A PWM battery charger is an example of such a device. When first connected to a discharged battery, the PWM may be 99%. This produces negative pulse type masking data. As the battery charges, the PWM is reduced. When the stable portion of the negative pulse is at least 2 samples wide, it produces rectangular type masking data. When the battery is nearly fully charged, the PWM approaches 1%. When the stable portion of the positive pulse becomes less than 2 samples wide, it produces positive type pulse masking data.

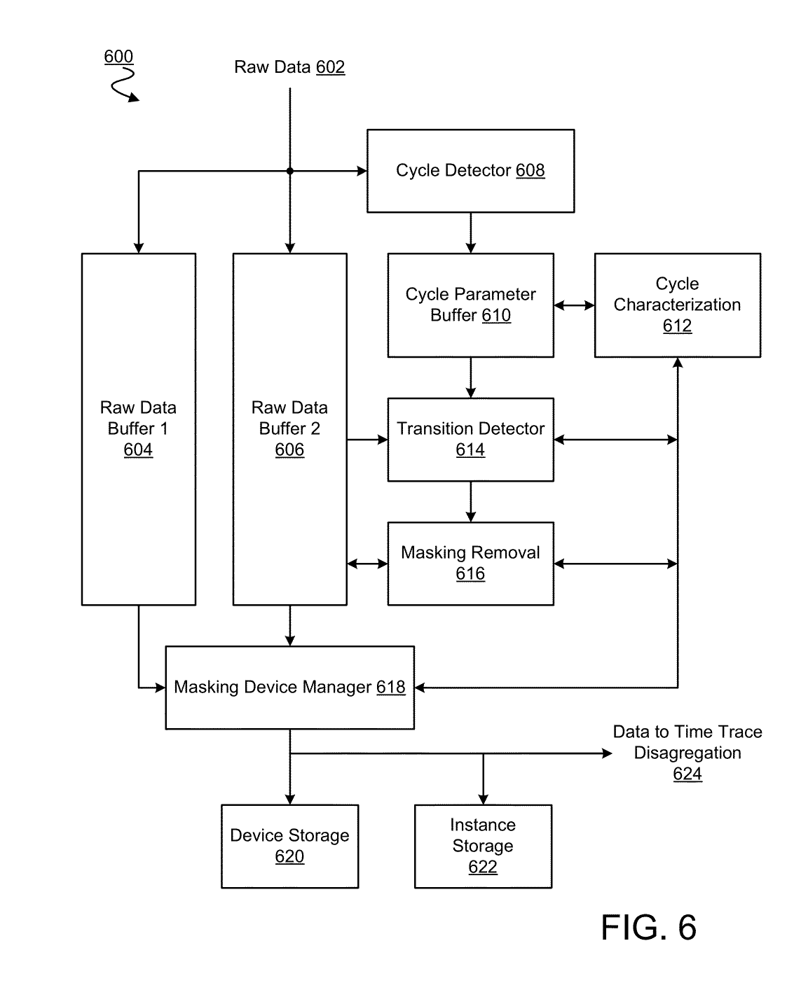

FIG. 6 is a flow diagram 600 of a preprocessing process and data flow in accordance with certain embodiments of the disclosed technology. This processing may be done separately for each service leg for each AC supply cycle, for example.

RAW DATA 602 may be provided by a monitor connected to the electrical service of a building, for example. Typically, the data contains samples of parameters from two service legs, e.g., residential split single-phase, or three service legs, e.g., commercial three-phase. The voltage and current of each service leg may be sampled by the monitor approximately 4,000 times per second and converted to digital values, typically 16 bit resolution. The monitor may synchronize this sampling to the 60 cycle AC supply so that the number of samples per AC cycle (typically 67) is the same for all cycles. These AC cycle samples may be processed digitally to provide a measure of the RMS voltage, RMS current, average power, and average reactive power for each AC cycle. These averages for each AC cycle may be reported by the monitor via wireless communication to provide the RAW DATA 602.

A CYCLE DETECTOR 608 may process each power sample to detect a masking data cycle. A masking data cycle is usually detected when a significant maximum power sample followed by a significant minimum power sample occur within a span of Max-Samples samples, typically 70 samples. The CYCLE DETECTOR 608 may determine a number of parameters that characterize the masking data cycle and may store these in a circular CYCLE PARAMETER BUFFER 610. If a significant minimum and maximum do not occur within Max-Samples, the parameters may be stored and the CYCLE DETECTOR 608 may be reset to detect a masking data cycle.

The RAW DATA 602 may be stored in a circular RAW DATA BUFFER 1 604 and RAW DATA BUFFER 2 606. A time trace disaggregation algorithm may use a maximum of 300 samples of a positive transition to identify a device. Samples of power, reactive power, and current may be used. The preprocessor generally provides a maximum of 300 sequential samples of data with the masking data removed. As described below, the removal process may use a similar number of samples before the positive transition to characterize the masking data. Therefore, the circular data buffers may be sized to store 600 samples of data. The CYCLE PARAMETER BUFFER 610 may be sized to store 300 masking data cycles, the maximum that could occur during 600 samples.

A CYCLE CHARACTERIZATION 612 generally processes the cycle parameters at the end of each masking data cycle, e.g., to detect if there is periodic masking data in the RAW DATA. If there are four consecutive masking data cycles that span less than Max-Samples samples, for example, the process signals other processes and components in the flow diagram 600 that masking data is present in the RAW DATA 602.

Alternatively or in addition thereto, the CYCLE CHARACTERIZATION 612 may be used to determine which of the four types of masking data best characterize the cycles, and to pass this characterization to other processes.

Alternatively or in addition thereto, the CYCLE CHARACTERIZATION 612 may be used to track long term maximum and minimum values of the power, reactive power, and current while masking data is present. These values may be determined by processing the parameters stored in the CYCLE PARAMETER BUFFER 610, for example.

A TRANSITION DETECTOR 614 may be active while masking data is present. The TRANSITION DETECTOR 614 may operate on the RAW DATA 602 and masking data cycles delayed by approximately 300 samples from the CYCLE DETECTOR 608. It may be used to detect positive and negative transitions that are associated with conventional devices that can be recognized and processed by a time trace disaggregation process, for example. By using the characterization information provided by the CYCLE CHARACTERIZATION 612, the CYCLE DETECTOR 608 may ignore transitions caused by the masking data.

When masking data is present and no conventional device transitions are detected, a MASKING REMOVAL 616 may be used to remove the masking data from the data stored in RAW DATA BUFFER 1 604, for example. In certain embodiments, this removal simply replaces the power, reactive power, and current sample values with the long term minimum values provided by the CYCLE CHARACTERIZATION 612.

When masking data is present and a conventional negative transition is detected, the MASKING REMOVAL 616 may be used to determine the most probable sample number within the masking data cycle when the transition occurs. The samples in RAW DATA BUFFER 1 604 before this sample number and in the masking data cycle may be replaced by the long term minimum values provide by the CYCLE CHARACTERIZATION 612. The MASKING REMOVAL 616 may then use the data in the CYCLE PARAMETER BUFFER 610 for masking data cycles after the negative transition to determine the long term minimums after the transition. Finally, the samples in RAW DATA BUFFER 1 604 after the negative transition and in the masking data cycle may be replaced by the long term minimums of the masking data cycles after the transition.

When masking data is present and a conventional positive device transition is detected, the TRANSITION DETECTOR 614 may signal the CYCLE CHARACTERIZATION 612, which may then gather and prepare information about the masking data. It may also possess the masking data cycle parameters that occur after the positive transition to determine the number of masking data cycles that must be processed before the MASKING REMOVAL 616 can be again used. The removal processes generally operate on a contiguous set of raw data that includes the masking data cycles with significant variations not caused by the masking data. This positive transition block typically spans less than 300 samples. The CYCLE CHARACTERIZATION 612 may then call one of five removal processes: CLIP REMOVAL, CHAOTIC REMOVAL, PERIODIC REMOVAL, RECTANGULAR REMOVAL, or PULSE REMOVAL.

Any single one or combination of these processes may be used to remove the masking data from the samples in RAW DATA BUFFER 1 604, for example. The processes generally use the characteristics of the masking data to optimally recover and preserve the characteristics used by the time trace disaggregation process. Each of these processes is described in detail below.

Data from the end of the circular RAW DATA BUFFER 1 604 may be sent to a time trace disaggregation process for processing, as indicated by 624. This data is typically delayed by the length of the buffer, typically 600 samples, from the RAW DATA 602 input.

A MASKING DEVICE MANAGER 618 may generate instances and devices that identify and track the masking devices. A masking instance is typically started when the masking data is detected. The characteristics of the masking data determined by the CYCLE CHARACTERIZATION 612 may be used to match the new masking instance with masking devices created by previous masking instances. If a similar device has not occurred before, then a new masking device may be created. While the masking instance is active, the current masking data characteristics may be periodically compared to the associated device. If it no longer matches, the instance is typically ended and a new instance may be created to represent the new masking device.

While a masking instance is active, the difference between the power samples in RAW DATA BUFFER 2 606 and the processed samples in RAW DATA BUFFER 1 604 is the power attributed to the masking instance and the associated masking device. These differences may be accumulated to determine the total energy. The average power may thus be determined by dividing the accumulated energy by the accumulated run time.

The masking instances and masking devices are generally compatible with the tracking, storage, and reporting used by existing time trace disaggregation processes. The MASKING DEVICE MANAGER 618 may communicate with such time trace disaggregation processes to create and store the instances and devices associated with masking devices in an INSTANCE STORAGE 622 and a DEVICE STORAGE 620, respectively.

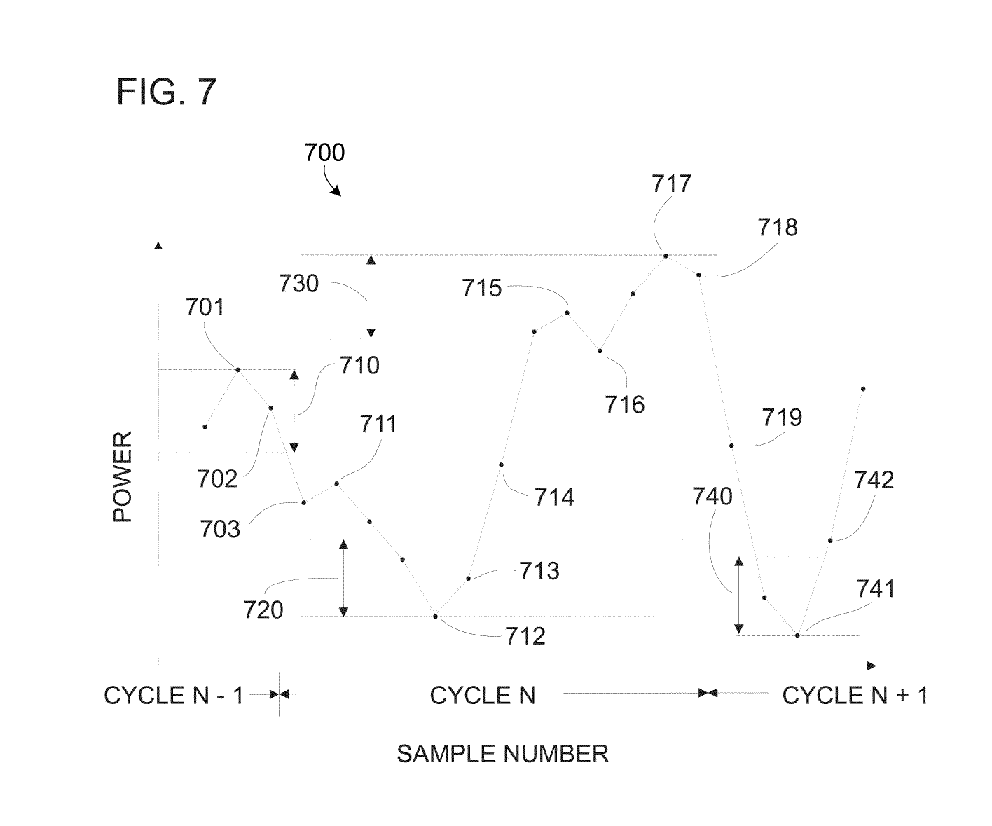

FIG. 7 is a graph 700 illustrating the samples of chaotic type power cycles and the thresholds used to detect a masking data cycle in accordance with certain embodiments of the disclosed technology. Each dot in the graph 700 represents one sample. The graph spans the end part of CYCLE N−1, all of CYCLE N, and the first part of CYCLE N+1.

The CYCLE DETECTOR 608 may use a threshold, e.g., 710, 720, 730, and 740, to provide hysteresis. The threshold may be set to default minimum, typically 4 watts, when there is no masking data. After masking data is detected, the threshold may be adjusted to a percentage, typically 25%, of the average peak-to-peak value of detected masking data cycles.

The CYCLE DETECTOR 608 has two states: S-Max, e.g., seeking maximum sample, and S-Min, e.g., seeking minimum sample. When in the S-Max state, the CYCLE DETECTOR 608 may compare the current sample with the current maximum value and, if greater, may save the new maximum value and its corresponding sample number. In the graph 700, sample 701 is the maximum for CYCLE N−1. If the current sample value is less then the maximum, the difference may be compared to the threshold value, which is represented by 710. If the difference is less than the threshold value, the state is not changed. The difference between sample 701 and 702 is less than threshold 710, however, so the state remains S-Max in this example.

The difference between sample 701 and sample 703 in the graph 700 exceeds the threshold 710, so the state is changed to S-Min. Here, sample 702 is the last sample of CYCLE N−1 and sample 703 is the first sample of CYCLE N. Sample 703 is the current minimum sample for CYCLE N. Sample 711 is greater than sample 703, but the difference is less than the threshold 720, so the state is not changed. As the successive samples are processed, each sample after 711 to sample 712 becomes the new current minimum sample. Sample 713 is greater than sample 712 (the current minimum sample) but, because the difference is less than threshold 720, the state remains S-Min.

The difference between sample 712 and sample 714 in the graph 700 exceeds the pertinent threshold 720, so the state is changed to S-Max. Sample 712 is the minimum sample for CYCLE N. Sample 714 is the current maximum sample for CYCLE N. Sample 715 is the current maximum sample when sample 716 is processed. The difference between sample 715 and 716 is less than the threshold, so the state remains S-Max.

In the graph 700, sample 717 is the current maximum sample when sample 718 is processed. The difference between sample 717 and 718 is less than the pertinent threshold 730, so sample 717 remains the current maximum sample for CYCLE N and the state remains S-Max.

The difference between sample 717 and sample 719 in the graph 700 is greater than the threshold 730, so the state changes to S-Min. Sample 718 is the last sample of CYCLE N and sample 719 is the first sample of CYCLE N+1 and the current minimum value in this example.

The following parameters may be determined by the CYCLE DETECTOR 608 to characterize each masking data cycle:

| | |
|---|---|
| Max-Value | The power value of the maximum sample |
| Max-Time | The sample number of the maximum sample |
| Min-Value | The power value of the minimum sample |
| Min-Time | The sample number of the minimum sample |
| Max-Pos-Dif | The maximum positive difference between |
| | successive power samples |
| Max-Pos-Time | The sample number when Max-Pos-Dif occurred |
| Max-Neg-Dif | The maximum negative difference between |
| | successive power samples |
| Max-Neg-Time | The sample number when Max-Neg-Dif occurred |
| Max-RPow-Value | The maximum reactive power during the cycle |
| Min-RPow-Value | The minimum reactive power during the cycle |
| Max-Cur-Value | The maximum current during the cycle |
| Min-Cur-Value | The minimum current during the cycle |
| Start-Time | The sample number of the first sample of the cycle |
| Num-Samples | The number of sample in the cycle |

A complete cycle generally begins with a transition from S-Max to S-Min, then a transition to S-Max, and then ends with a transition from S-Max to S-Min. Therefore, the minimum value for Num-Samples is usually 2.

If a cycle does not complete within Max-Samples, the cycle is ended. Typically, Max-Sample is set to 70, which is about 1.2 seconds. A cycle with Num-Samples=Max. Samples is an incomplete cycle and is not considered a masking cycle. However, the parameters do represent the data during the span of the cycle.

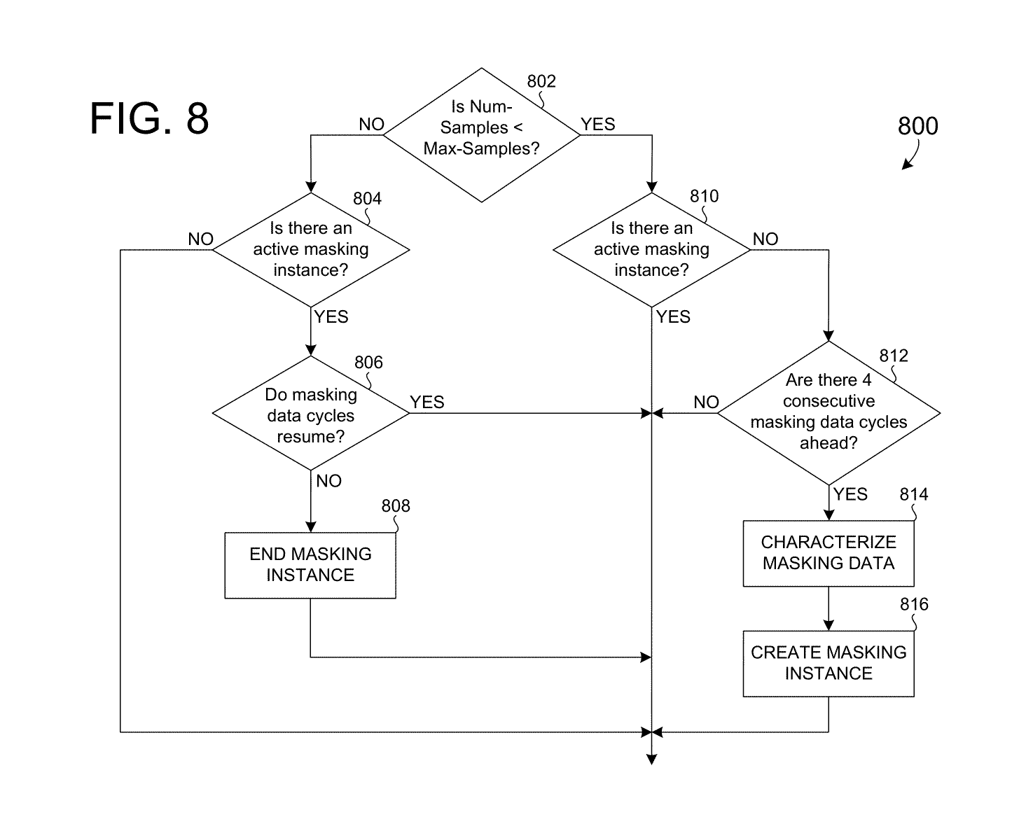

FIG. 8 is a flow diagram 800 of a process used by the CYCLE CHARACTERIZATION 612 of FIG. 6 to determine when masking data is present in accordance with certain embodiments of the disclosed technology.

Each masking data cycle may be processed. The information in the masking data cycle may be processed when the end of the masking data cycle is more than 300 samples after the RAW DATA 602 has been copied to the RAW DATA BUFFER 1 604, for example. This masking data cycle is referred to herein as the “focus cycle.” The sample number of the end time of the focus cycle is referred to herein as the “processing time.” The selection of the processing time ensures that at least 4 masking data cycles are stored in the CYCLE PARAMETER BUFFER 610 with end times equal to or greater than the processing time.

When the focus cycle is processed, the first test determines if it represents a masking data cycle (Num-Sample<Max-Samples), as indicated by 802 or an incomplete cycle (Num-Sample=Max-Samples). If it is an incomplete cycle, a test determines if there is an active masking instance, as indicated by 804. If there is an active masking instance, a test determines if masking data cycles return in the future, e.g., within 4 masking data cycles, as indicated by 806. The CYCLE DETECTOR 608 can be disrupted by positive and negative transitions caused by conventional devices. The CYCLE CHARACTERIZATION 612 may bridge the incomplete cycles so the masking instance is contiguous through conventional transitions.

If masking data cycles do not continue after the incomplete focus cycle, the active masking instance is ended, as indicated by 808.

If the focus power cycle is a complete cycle, a test determines if there is an active masking instance, as indicated by 810. If there is an active masking instance, there is nothing else to do and this process is complete.

If the focus cycle is complete and there is no active masking instance, then a test determines if there are four consecutive masking data cycles in the future, as indicated by 812. If there are not four consecutive masking data cycles in the future, a masking instance is not starting and there is nothing else to do and this process is complete.

If there are four consecutive power cycles, then a masking instance is started. The masking data may be characterized using the complete masking data cycles in the future by a CHARACTERIZE MASKING DATA process, as indicated by 814. Then a CREATE MASKING INSTANCE process may signal the MASKING DEVICE MANAGER 618 to create a new masking instance, as indicated by 816.

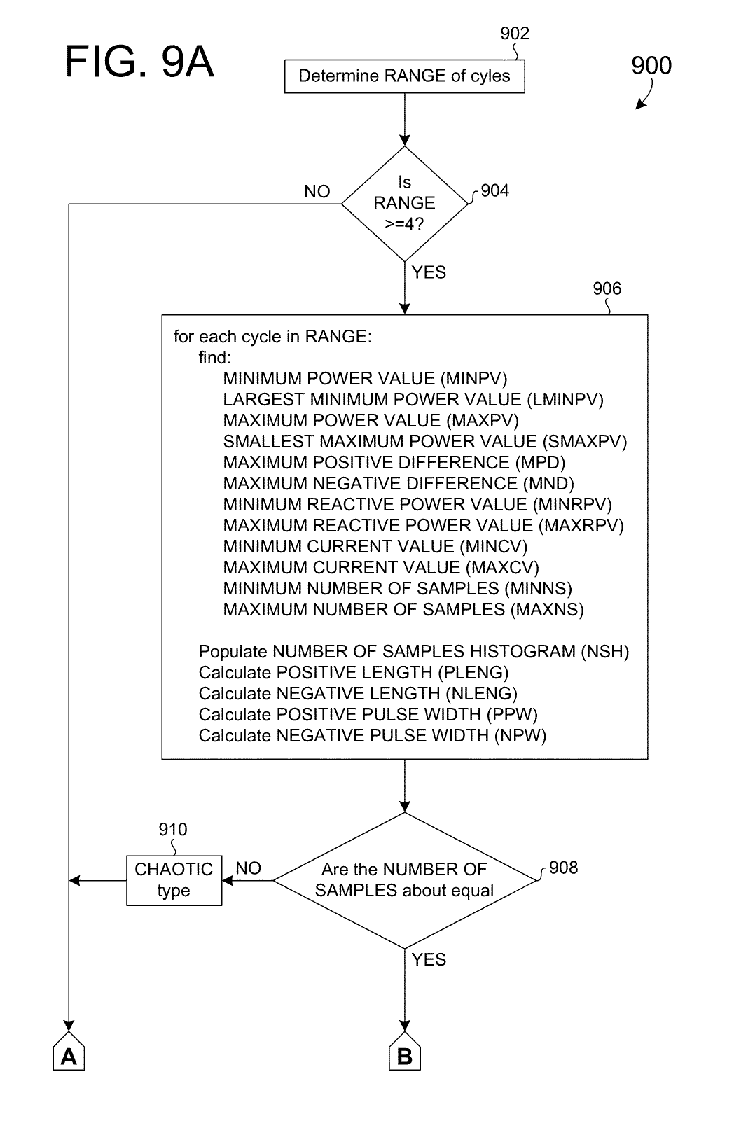

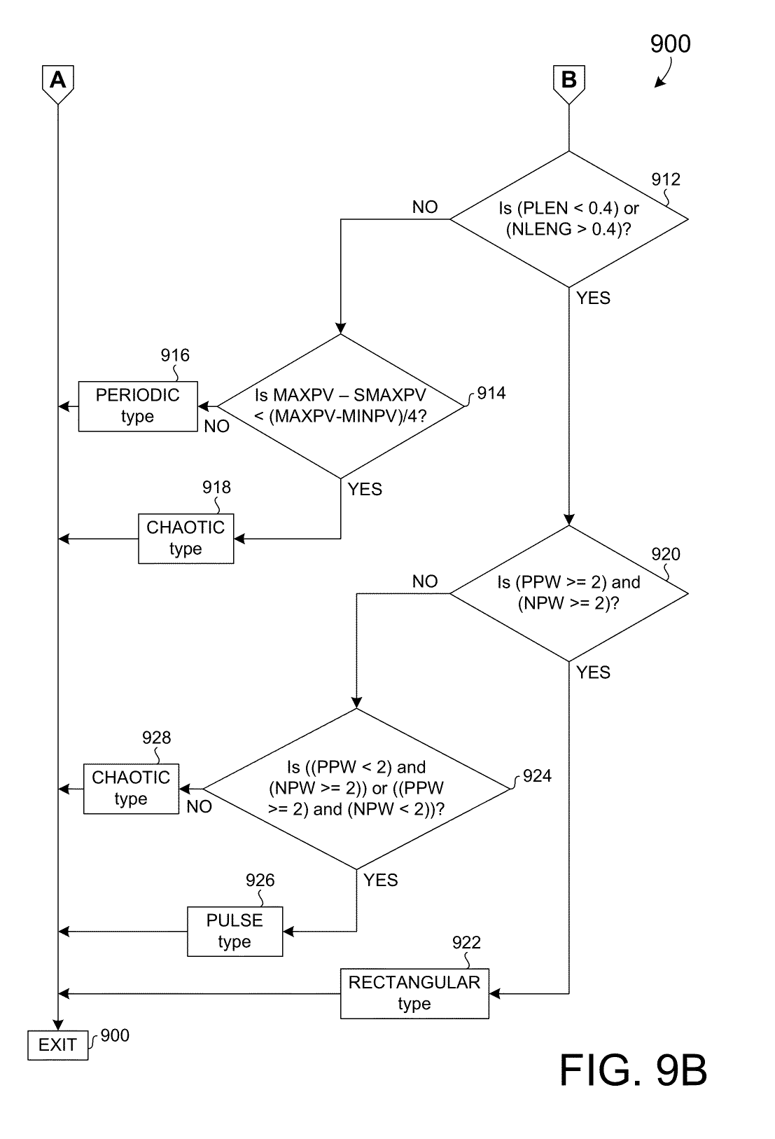

FIGS. 9A and 9B together constitute a flow diagram of a CHARACTERIZE MASKING DATA process 900 within the CYCLE CHARACTERIZATION 612 of FIG. 6 to determine the type of masking data present in accordance with certain embodiments of the disclosed technology. Such a CHARACTERIZE MASKING DATA process 900, see, e.g., 814 of FIG. 8, may first determine a RANGE of masking data cycles to use, as indicated by 902. In the example, all of the masking data cycles in the RANGE must be complete cycles and there must be at least four and no more then 20 complete cycles. Additionally, there must not be a detectable conventional transition within the range. The process for detecting conventional transitions is described in a following section. A determination is made as to whether the RANGE is at least 4, as indicated by 904.

If the RANGE is less than 4, then CHARACTERIZE MASKING DATA process 900 cannot make a determination of the masking type and it is not changed. The CHARACTERIZE MASKING DATA process 900 may also be called by the TRANSITION DETECTOR 614 when a conventional transition is detected and periodically by the MASKING DEVICE MANAGER 618. If it is not possible to make a determination of the masking data type, then the previously determined type and characterization may be used. When called by the CYCLE CHARACTERIZATION 612 at the start of a masking instance, the masking type is typically undefined if the RANGE is less than 4. While a clip removal process of the MASKING REMOVAL 616 can still process the RAW DATA 602, the other removal processes typically cannot. If a conventional positive transition is detected before the masking type is determined, the RAW DATA 602 is generally not modified during the transition period. After the masking instance is started, the MASKING DEVICE MANAGER 618 may call the CHARACTERIZE MASKING DATA process 900 for each cycle until the masking type is determined.

If the RANGE has at least 4 complete cycles, then the parameters stored in the CYCLE PARAMETER BUFFER 610 for each masking data cycle in the RANGE may be processed to determine the following parameters, as indicated by 906:
1. MINIMUM POWER VALUE (MINPV)—the smallest Min-Value in the RANGE
2. LARGEST MINIMUM POWER VALUE (LMINPV)—the largest Min-Value in the RANGE
3. MAXIMUM POWER VALUE (MAXPV)—the largest Max-Value in the RANGE
4. SMALLEST MAXIMUM POWER VALUE (SMAXPV)—the smallest Max-Value in the RANGE
5. MAXIMUM POSITIVE DIFFERENCE (MPD)—largest Max-Pos-Dif in the RANGE
6. MAXIMUM NEGATIVE DIFFERENCE (MND)—largest Max-Neg-Dif in the RANGE
7. MINIMUM REACTIVE POWER VALUE (MINRPV)—the smallest Min-RPow-Value in the RANGE

8. MAXIMUM REACTIVE POWER VALUE (MAXRPV)—the largest Min-RPow-Value in the RANGE

9. MINIMUM CURRENT VALUE (MINCV)—the smallest Min-Cur-Value in the RANGE
10. MAXIMUM CURRENT VALUE (MAXCV)—the largest Min-Cur-Value in the RANGE
11. MAXIMUM NUMBER OF SAMPLES (MAXNS)—the largest Num-Samples in the range
12. MINIMUM NUMBER OF SAMPLES (MINNS)—the smallest Num-Samples in the range

While the masking data cycles are processed, a NUMBER SAMPLES HISTOGRAM (NSH) may be prepared. This is typically an array with the number of elements being equal to Max-Samples. All elements in the NSH may be initialized to zero. The Num-Samples value for each cycle may be used to index NHS, and that element may be incremented. After all of the masking data cycles are processed, each element usually contains the number of cycle with Num-Samples being equal to the element index.

While the masking data cycles are processed, the parameters PLENG (POSITIVE LENGTH) and NLENG (NEGATIVE LENGTH) may be calculated. These are, respectively, the average value of MPD/(MAXPV−MINPV) and MND/(MAXPV−MINPV). These parameters generally characterize the normalized average of the maximum positive and the negative transitions for the cycles in the RANGE.

While the masking data cycles are processed, the MINIMUM POSITIVE PULSE WIDTH (PPW) and MINIMUM NEGATIVE PULSE WIDTH (NPW) may be determined. The Pos-Time and Neg-Time parameters may be used to determine a range that is indexed to power samples in the RAW DATA BUFFER 2 606. That is, the data values in this buffer are essentially unaffected by any process. The power samples between each sequential Pos-Time and Neg-Time may be tested for max-stability. A sample is generally considered max-stable if the difference between Max-Value and the sample value is less than 10% of Max-Value. The number of consecutive max-stable samples between Pos-Time and Neg-Time may be counted, and the PPW may be set to the smallest of these numbers. Likewise, the power samples between each sequential Neg-Time and Pos-Time may be tested for min-stability. A sample is generally considered min-stable if the difference between Min-Value and the sample is less than 10% of Min-Value. The number of consecutive min-stable samples between Neg-Time and Pos-Time may be counted, and the NPW may be set to the smallest of these numbers.

After the cycles in the RANGE are processed, a first test determines if the NUMBER OF SAMPLES are about equal for all cycles, as indicated by 908. The sum of all triples of adjacent elements of NHS may be calculated, If all of the sums are less than 75% of the number of cycles in the RANGE, for example, then the masking data is CHAOTIC type, as indicated by 910. That is, the period of the masking data is not sufficiently consistent to help the removal processes.

If, however, at least one of the triplet sums is at 75% of the number of cycles in the RANGE in the example, then the periods of the masking cycle are sufficiently similar to help the removal processes.

Another test determines whether the masking data has fast transitions between Min-Value and Max-Value, as indicated by 912. A fast transition typically occurs within two samples, so PLENG and/or NLENG should be at least 0.5 if the transition is fast. If either PLENG or NLENG is less than 0.4, then at least one of the masking data cycle transition is slow, so the masking data is either PERIODIC type or CHAOTIC type. If both positive and negative transitions are fast, then the masking data is either RECTANGULAR type or PULSE type.

Another test determines if the peak-to-peak magnitude is consistent for all power cycles in the RANGE, as indicated by 914. The variation in the maximum value is (MAXPV−SMAXPV) and the peak-to-peak value is (MAXPV−MINPV). If the variation in the maximum is less than 25% of the peak-to-peak value, then the masking data is PERIODIC type, as indicated by 916. If the peak-to-peak variation is large, the masking data type is CHAOTIC, as indicated by 918.

RECTANGULAR type masking data has at least two samples in each masking data cycle that are stable and near the minimum value MINPV, and at least two samples that are stable and near the maximum value MAXPV. A test may be used to determine whether both PPW and NPW are >=2, as indicated by 920. If they are, then the masking data is RECTANGULAR type, as indicated by 922. If not, a determination may be made as to whether ((PPW<2) and (NPW>=2)) or ((PPW>=2) and (NPW<2)), as indicated by 924. If so, then the masking data is PULSE type, as indicated by 926. If not, then the masking data is CHAOTIC type, as indicated by 928.

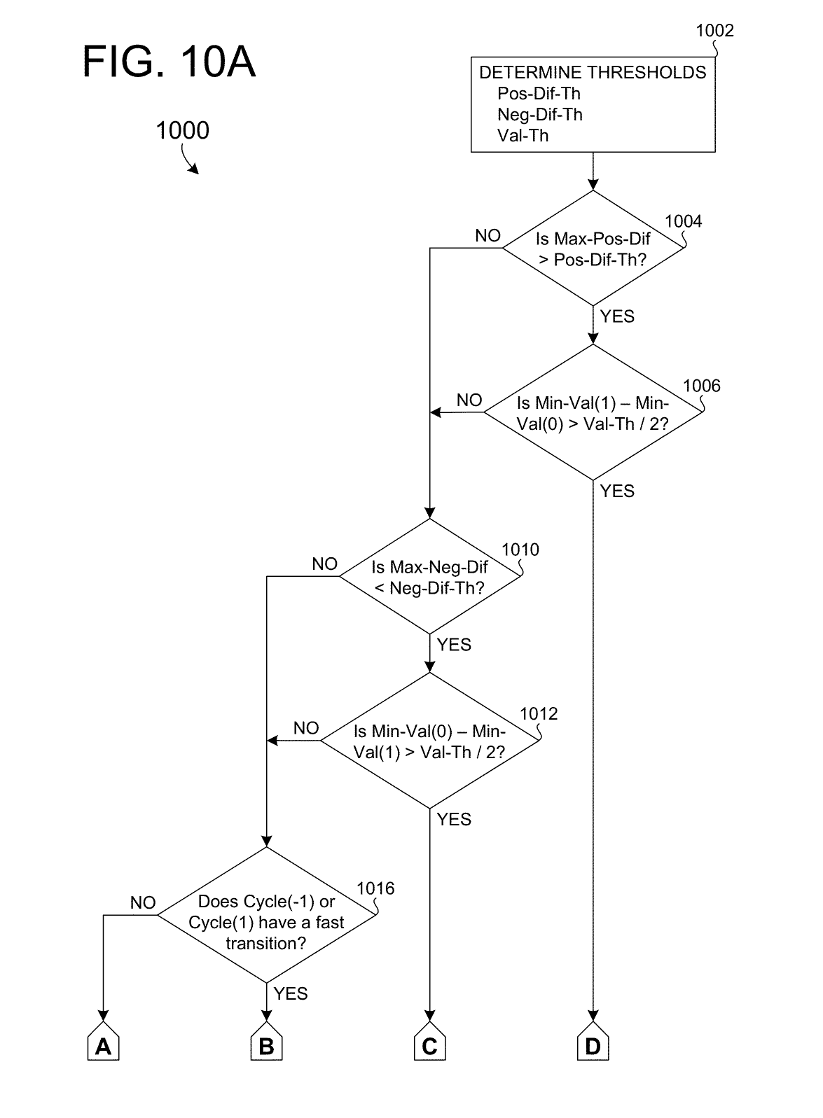

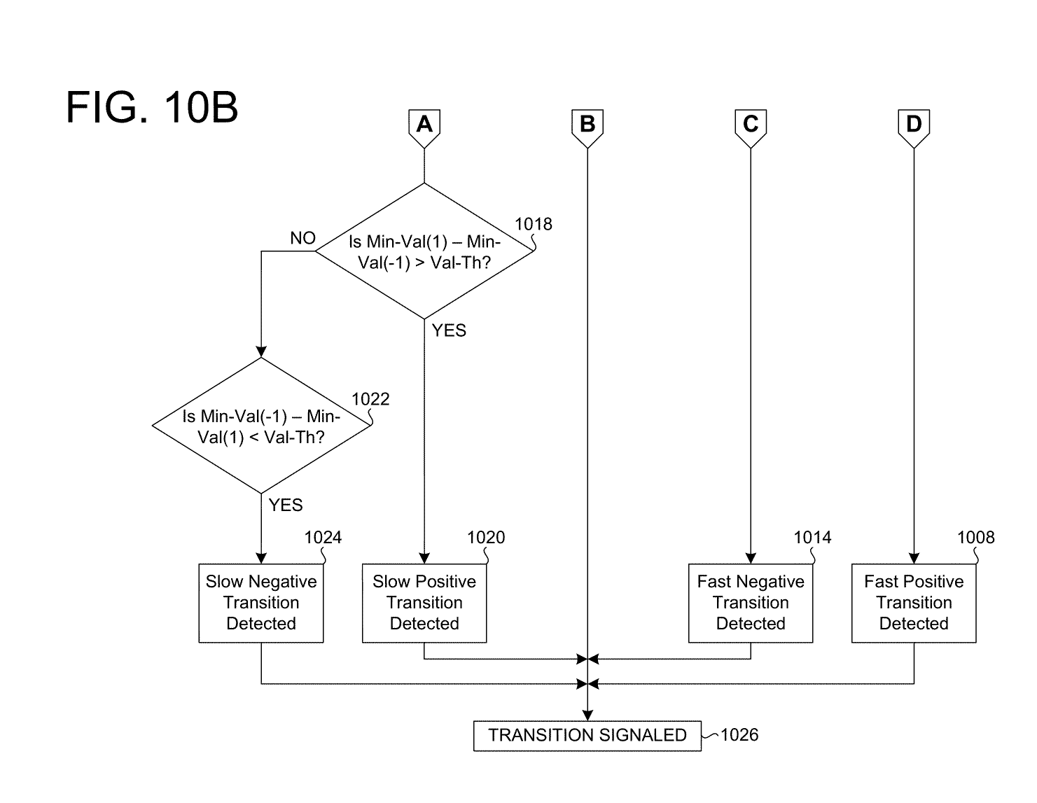

FIGS. 10A and 10B together constitute a flow diagram 1000 of a TRANSITION DETECTOR process, such as the TRANSITION DETECTOR 614 of FIG. 6, in accordance with certain embodiments of the disclosed technology. This process 1000 may be used to detect positive and negative transitions that are not caused by the masking data. The process 1000 is generally active only when there is masking data present. When a negative transition is detected, the MASKING REMOVAL 616 may use a clip removal process to remove the masking data. When a positive transition is detected, the appropriate removal process may be signaled.

The TRANSITION DETECTOR 614 may first determine the thresholds Pos-Dif-Th, Neg-Dif-Th, and Val-Th for detecting transitions based on the behavior of the masking data cycles before the focus cycle in the CYCLE PARAMETER BUFFER 610, as indicated by 1002. Only masking data cycles that do not contain a transition and do not occur within 300 samples after a conventional positive transition are used when determining these thresholds. The thresholds generally depend on the number of masking data cycles used to determine their values. For CHAOTIC and PERIODIC type masking data a minimum of four masking data cycles and a maximum of twenty cycles may be used. For RECTANGULAR and PULSE type masking data, all cycles since the last conventional transition may be used. Tables of scale values for each threshold are provided for the range of four to twenty cycles. These scale values range from about 5 to about 1.5. For more masking data cycles than twenty, the scale value for 20 cycles is exponentially reduced to a limit value of about 1.2 for 1000 cycles.

For the range of cycles used in the determination, Pos-Dif-Th generally equals its scale value times the MPD, i.e., long term maximum positive difference. Neg-Dif-Th generally equals its scale value times the MND, and Val-Th generally equals its scale value times the difference between the long term LMINPV and MINPV.

A first test may be used to determine whether the Max-Pos-Dif of the focus cycle is greater than Pos-Dif-Th, as indicated by 1004. If it is greater, a second test may be made to verify the positive transition, as indicated by 1006. For conventional devices, there will typically be a significant increase in power after the transition. The Min-Val of the focus cycle, i.e., Min-Val(0), may be subtracted from the Min-Val of the following cycle, i.e., Min-Val(1), and the difference compared to Val-Th/2. If the difference is greater, then a fast positive transition is detected and may be signaled, as indicated by 1008 and 1026, respectively.

If there is no fast positive transition, a test may be used to determine whether the Max-Neg-Dif of the focus cycle is less than Neg-Dif-Th, as indicated by 1010. If it is less, then another test may be used to determine whether there is a significant power decrease following the negative transition. For example, the Min-Val of the following cycle may be subtracted from the Min-Val of the focus cycle and the difference compared to Val-Th/2, as indicated by 1012. If the difference is greater, then a fast negative transition is detected and may be signaled, as indicated by 1014 and 1026, respectively; otherwise, a determination may be made as to whether Cycle(−1) or Cycle(1) have a fast transition. If so, the transition may be signaled as indicated by 1026. If not, the process 1000 may proceed to 1018, which is described below.

The Max-Pos-Dif and Max-Neg-Dif may be greater than 1000 watts for some masking data. These differences are generally greater than the differences produced by the transitions of many conventional devices of interest. For many sources of masking data, the Min-Val of each masking data cycle is very stable, so transitions obscured by large difference thresholds can be detected by cycle-to-cycle changes in the Min-Val of the cycles. When hundreds of these cycles occur without a conventional transition, the threshold for detection can be reduced to about 10% more than the long term variation in the Min-Val.

Slow transitions may be detected by comparing the Min-Val of the cycle before the focus cycle (Min-Val(−1)) and the cycle after the focus cycle (Min-Val(1)), as indicated by 1018. These comparisons are done only if these cycles have no fast transitions. If the difference between the Min-Val of these cycles is greater than the Val-Th, then a slow positive transition is detected and signaled, as indicated by 1020 and 1026, respectively; otherwise, another determination with regard to the difference between the Min-Val of the cycles and Val-Th may be made, as indicated by 1022. If the difference is less than the Val-Th, then a slow negative transition is detected and signaled, as indicated by 1024 and 1026, respectively.

For the negative variant of PULSE type, the Max-Val of each cycle is typically very stable. For this type, slow transitions may be detected by a similar process that test for changes in Max-Val.

The TRANSITION DETECTOR 614 may signal the CYCLE CHARACTERIZATION 612 when a positive transition is detected. The CYCLE CHARACTERIZATION 612 may verify the masking type and determine the masking data characterization most appropriate for the determined type. It may also determine the number of masking data cycles that must be processed by the removal process. The first cycle generally includes the positive transition and the last cycle is typically selected to limit the transition data block to less than 300 samples or until the Min-Val for four consecutive masking data cycles vary by less than Val-Th. The CYCLE CHARACTERIZATION 612 may then activate the appropriate removal process for the masking data type.

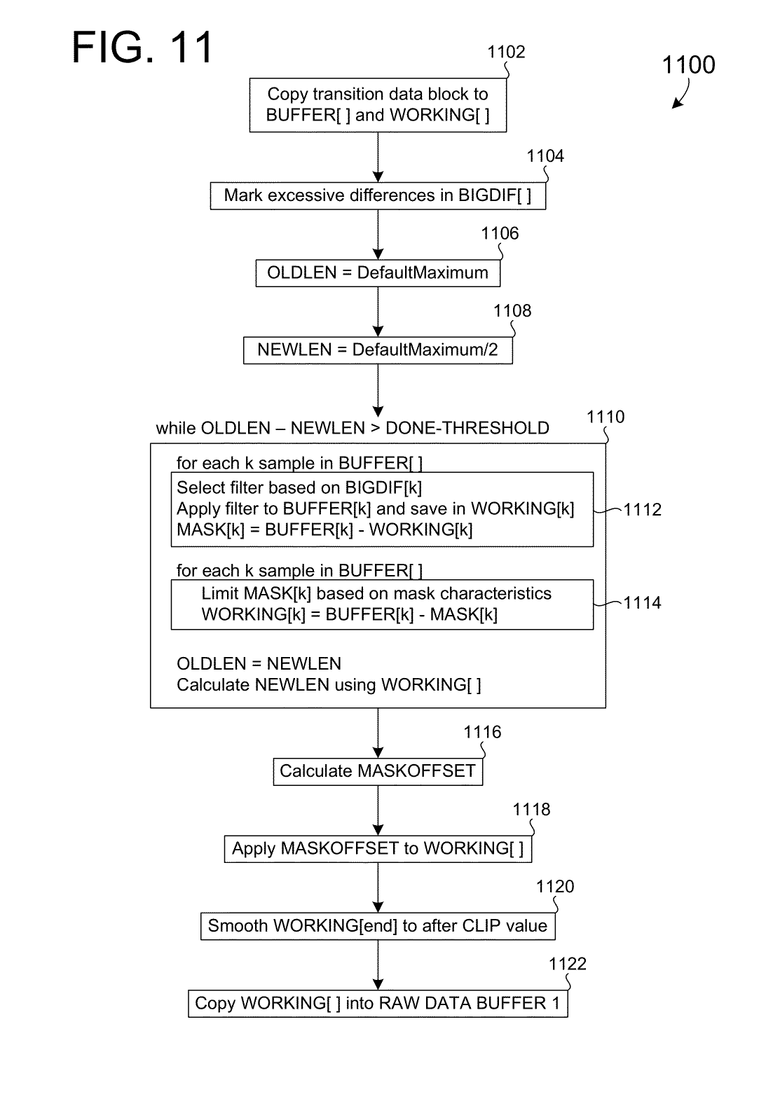

FIG. 11 is a flow diagram of a CHAOTIC REMOVAL process 1100, such as may be called by the CYCLE CHARACTERIZATION 612 of FIG. 6, in accordance with certain embodiments of the disclosed technology. The process 1100 is typically a constrained incremental filter process that iterates until the process no longer improves the result. The process 1100 may operate separately for power, reactive power, and current.

Data spanning the samples of the transition data block are copied into one dimensional arrays BUFFER[ ] and WORKING[ ], as indicated by 1102. The differences between successive pairs of samples may be compared to the MPD and MND values. If the difference exceeds one of these, then the first sample of the pair may be marked in the BIGDIF[ ] buffer (+1 for positive, −1 for negative, 0 for less than MPD and MND), as indicated by 1104. The non-zero values mark the rapidly changing portions of the conventional transition that are preserved by the process.

The starting positive transition of the conventional positive transition occurs within the first masking data cycle. The Max-Pos-Time is generally assumed to be the start sample. Samples before this sample may be set equal to the long term minimum values used by the MASKING REMOVAL 616 for the previous cycle. For each sample before the start sample, the value in BIGBUF[ ] may be set to −2.

A measure of the length of the trace is generally used to represent the completeness of the removal process. The measure is the sum of the square roots of (1+DIF*DIF) for each sample pair in the transition data block. This measure is the hypotenuse of a right triangle formed by the difference between sample pairs separated by one sample. This hypotenuse is the length between samples, and the sum of these is a measure of the total length. The variable OLDLEN represents the length after the last iteration, and NEWLEN represents the length after the most resent iteration. OLDLEN and NEWLEG are initialized to values that ensure process block 1110, described below, is iterated at least two times. In the example, OLDLEN is set to a value DefaultMaximum and NEWLEN is set to half that value, i.e., DefaultMaximum/2, as indicated by 1006 and 1008, respectively.

The process block 1110 may be repeated for as long as the difference in the measure of length between successive iterations is significant. The value of DONE-THRESHOLD may be adjusted to account for the average magnitude of the conventional positive transition. This adjustment generally makes the required improvement of the iterations to be the same percentage for all sized conventional positive transitions.

Process block 1112 may be executed for each sample k in BUFFER[ ]. In the example, the first step is to select an appropriate filter function based on the contents of BIGDIF[k], and the results of filtering the value in WORKING[k] are saved in WORKING2[k].

If BIGDIF[k] is equal to 0, one of two filter functions may be selected based on the value of MINNS. If MINNS<20, for example, the fast filter function may be used. The output of the fast filter function is (0.5*WORKING[k−1]+0.5*WORKING[k+1]). This is simply the average of the sample before and after sample k. If MINNS>=20, the slow filter function may be used. The output of the slow filter is (0.15* WORKING[k−2]+0.35*WORKING[k−1]+0.35*WORKING[k+1]+0.15* WORKING[k+2]. This is a weighted average of the two samples before and the two samples after the sample k.

If BIGDIF[k] is equal to −2, WORKING2[k] may be set equal to the value used by CLIP REMONAL.

If BIGDIF[ ] is equal to +1 or −1 for any of the samples used by the filter function, then the filter function may be modified so that the large differences are not suppressed. For example, if BIGDIF[k]=+1, the value of WORKING[k+1] is larger than can be caused by the masking data. The modified fast filter function is (0.5*WORKING[k−1]+0.5*WORKING[k]) so that the value of WORKING[k+1] does not effect the value of WORKING2[k]. In a similar manner, all filter functions may be modified to eliminate the influence of sample values associated with differences that are greater than occur in the masking data.

In the example, MASK[k] contains the difference between the newly filtered value in WORKING2[k] and the original value in BUFFER[k]. The samples in MASK[ ] should have the same characteristics as the masking data. Process block 1114 may be used to limit the values in MASK[ ] so that the peak-to-peak variations and the maximum positive and negative differences do not exceed those of the masking data. The new values in WORKING[ ] may be set to the values of BUFFER[ ]-MASK[ ].

The value of OLDLEN may then be replaced by the value of NEWLEN. A new value for NEWLEN may be calculated using the newly filtered values in WORKING[ ], as indicted by 1110.

Process block 1110 may be repeated until the measure of length becomes stable. When stable, the behavior of the values in MASK[ ] generally resemble the behavior of the samples of masking data. The conventional positive transition with the masking data removed may be stored in WORKING[ ].

The filtering processes generally causes the average of the values in MASK[ ] to be approximately zero. The MASKING REMOVAL 616 may use the long term minimum value of the masking data. The data in MASK[ ] may be offset in a similar manner so that transitions between samples processed by the MASKING REMOVAL 616 are not artificially offset from the samples processed by the CHAOTIC REMOVAL process 1100. The value of MASKOFFSET represents the difference between the average value and the minimum value of the samples in MASK[ ], and is calculated at 1116. The value of MASKOFFSET (a positive value) may then be subtracted from the samples in WORKING[ ] beginning at the start of the conventional positive transition, as indicated by 1118.

The final value in WORKING[ ] may differ from the value used by the CLIP REMOVE process after transition data block. The transition between these values may be smoothed, as indicated by 1120, by using linear interpolation for four samples between these two values, for example.

The values in WORKING[ ] may be written to their corresponding sample values in RAW DATA BUFFER1 604, as indicated by 1122. This completes the process 1100 for one parameter. The process 1100 may then be repeated for each of the three remaining parameters.

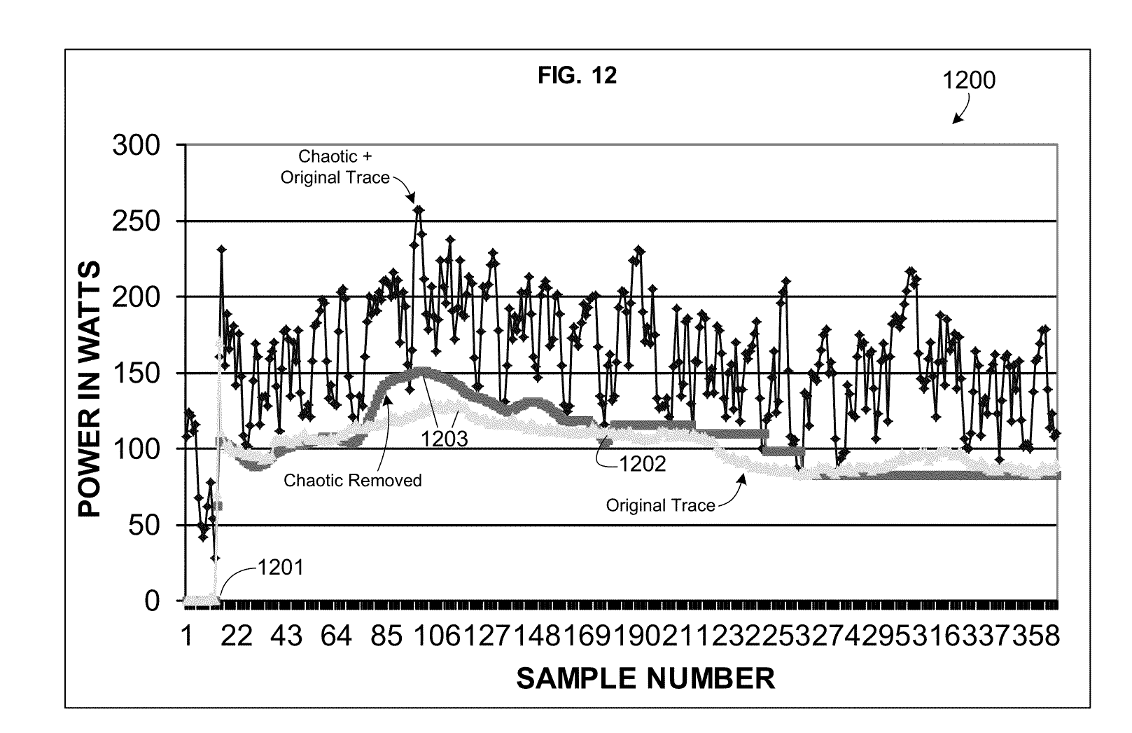

FIG. 12 is an overlay graph 1200 of power samples illustrating the typical results of a CHAOTIC REMOVAL process, such as the CHAOTIC REMOVAL process 1100 of FIG. 11, in accordance with certain embodiments of the disclosed technology. The graph 1200 shows a combination of chaotic data and a conventional positive transition, positive transition after processing by the CHAOTIC REMOVAL process, and the expected original positive transition.

A first trace in the graph 1200 represents the combination of the masking data and the conventional positive transition of a typical device. The shape of the positive transition is obscured in the example. Here, the TRANSITION DETECTOR 614 has detected a fast positive transition at sample 1201. The masking data cycles in the transition data block span from three samples before sample 1201 to sample 1202.

A second trace in the graph 1200 represents the results of processing by the MASKING REMOVAL 616 and the CHAOTIC REMOVAL process 1100. Here, the samples in the transition data block have been processed by the CHAOTIC REMOVAL process 1100 and the samples before and after the transition data block have been processed by the MASKING REMOVAL 616. The samples after sample 1202 show small step changes at the boundary between power cycles. These show changes in long term minimum power value MINPV.

A third trace in the graph 1200 represents the expected conventional positive transition. Here, the features of the second and third graphs are sufficiently similar that the conventional time trace disaggregation process associates these conventional positive transitions to the same device. The important features in this example are the initial peak and a slow increase in power to a maximum at 1203, which is followed by a slow decrease to a stable value of about 80 watts.

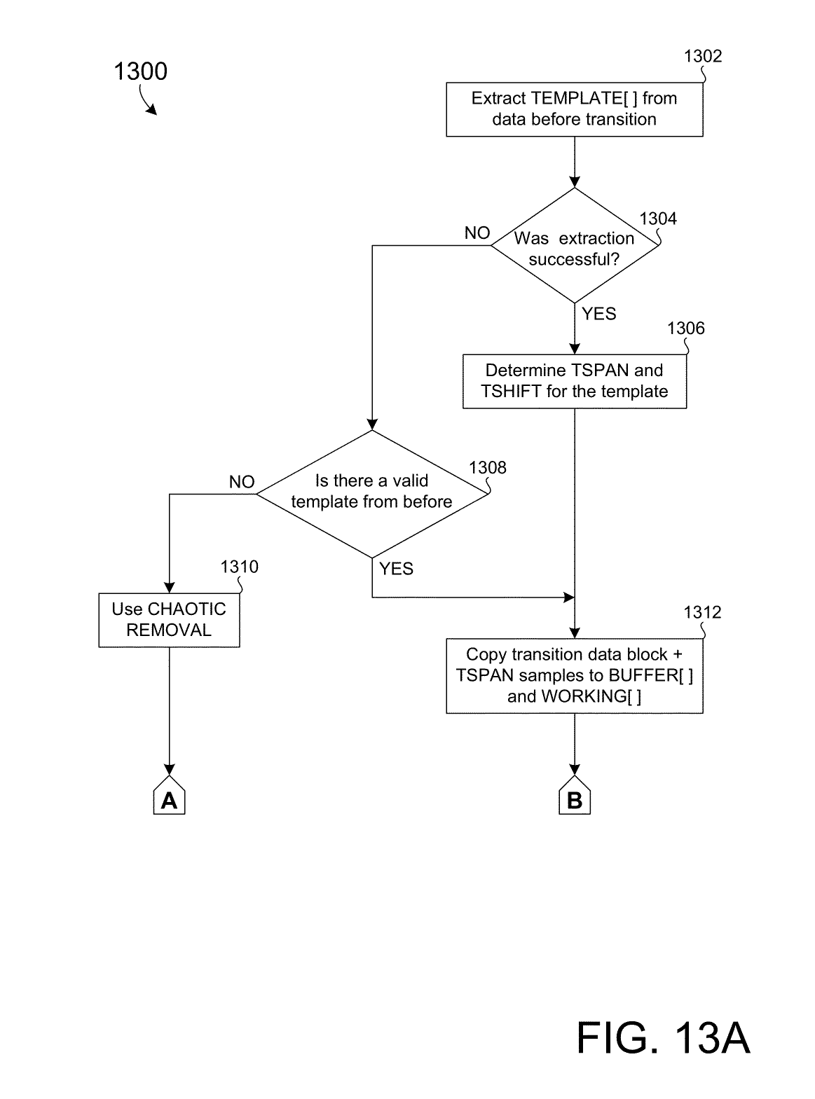

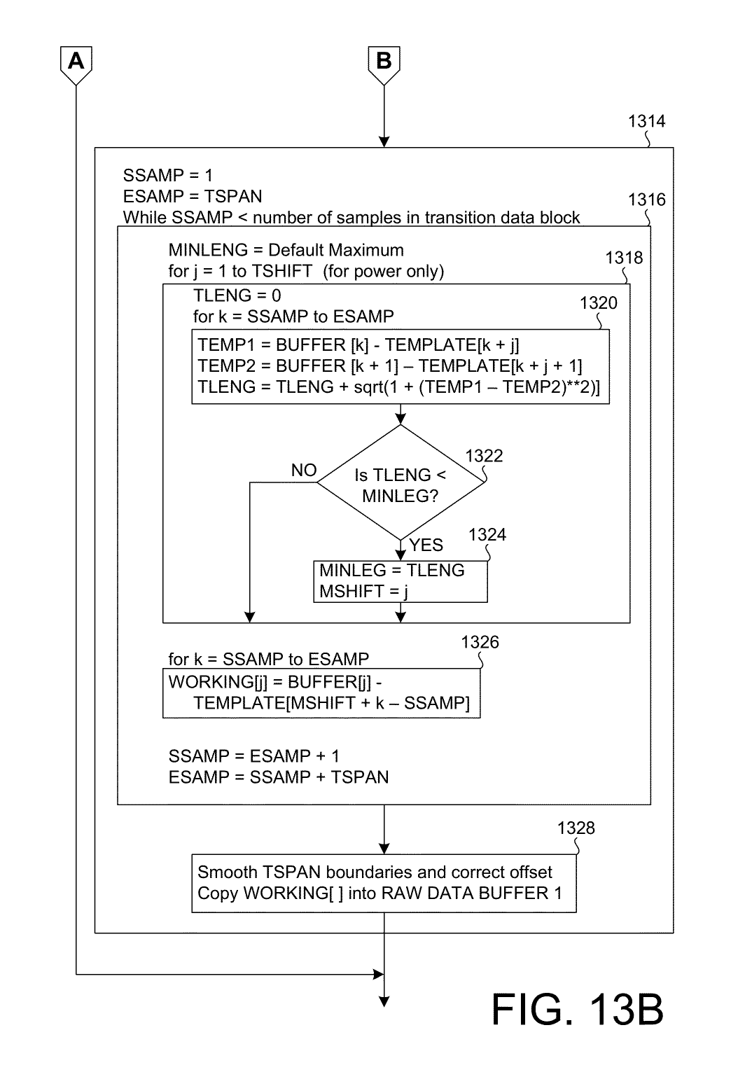

FIGS. 13A and 13B together constitute a flow diagram of a PERIODIC REMOVAL process 1300, such as may be called by the CYCLE CHARACTERIZATION 612 of FIG. 6, in accordance with certain embodiments of the disclosed technology. Periodic type masking data generally repeats its data pattern accurately, and the differences between samples are typically relatively small compared to those of rectangular and pulse type masking data. The PERIODIC REMOVAL process 1300 may subtract a template of the masking data from the raw data, adjusting the relative sample offset of the template to minimize the measure of length, as described above. The template span, e.g., number of samples, is typically small compared to the span of the transition data block. The template may be applied repeatedly and sequentially to sub-spans of the transition data block.

For processing convenience, the samples may be processed in reverse order. The newest sample, e.g., largest sample number, may be stored in the first element of all buffers, and the oldest sample, e.g., smallest sample number, may be stored in the last element. The removal process generally starts at the end of the conventional positive transition where the data values are relatively stable, and ends at the beginning of the transition where values vary rapidly.

The PERIODIC REMOVAL process 1300 may first attempt to extract TEMPLATE[ ] from the RAW DATA BUFFER 1 604, as indicated by 1302, where TEMPLATE[ ] is a two dimensional array with elements to store the templates for power, reactive power, and current. The masking data cycles before the positive transition may be tested to verify stability and the absence of any detectable transitions not caused by the masking data. If there are at least four sequential masking data cycles spanning a combined total of more than 2*Max-Samples, for example, then the TEMPLATE[ ] can be extracted. The extraction process may copy, e.g., in reverse order, the power samples into a temporary buffer with 2*Max-Sample elements, and subtract the average value of all the samples from each sample. The span (TSPAN) of the template represents a multiple of the average Num-Samples of the selected masking data cycles. The multiple represents the minimum that results in a TSPAN greater than Max-Samples/2. The number of masking data cycles in TSPAN may be between 1 and Max-Samples/4.

The template may then be processed to verify that a first section of TSPAN samples is nearly identical to the adjacent second section of TSPAN samples. Each sample of the first section may be subtracted from the corresponding sample of the second section, and the measure of length may be calculated for the resulting TSPAN of samples. The sample offset between first and second corresponding samples is nominally TSPAN samples, but the actual masking data cycle period may not be an integer multiple of AC cycles. The measures of length for offsets of TSPAN−2, TSPAN−1, TSPAN, TSPAN+1, and TSPAN+2 may be calculated. If any measure of length is less than a small threshold, then the template is validated.

If the template is validated, the power samples in the temporary buffer may be copied to TEMPLATE[ ]. The corresponding samples of reactive power and current may be corrected for offset using their respective average values and copied into TEMPLATE[ ].

The final value of TSPAN may be set to the value of the offset that had the smallest measure of length and the value of TSHIFT may be set to TSPAN+2, as indicated by 1306.

If the template extraction was not successful, then a test may be used to determine whether there is an existing valid template, as indicated by 1308. The template is generally considered valid if there has been no interruption of the masking data and if the periodic tests made by the MASKING DEVICE MANAGER 618 confirm that the characterization of the masking data has not changed since the template was extracted.

If there is no valid template, then a CHAOTIC REMOVAL process, such as the CHAOTIC REMOVAL process 1100 of FIG. 11, may be activated, as indicated by 1310. This removal process is generally less accurate but overall better than using no removal process.

If there is a valid template, the transition block data for power, reactive power, and current may be copied, e.g., in reverse order from RAW DATA BUFFER1 604 to BUFFER[ ] and WORKING[ ] (two dimensional arrays), as indicated by 1312. The extraction process generally works on whole sub-blocks of TSPAN samples. The span of the transition block data is usually not an even multiple of TSPN. Therefore, TSPAN additional samples are typically copied to these buffers to ensure that there are sufficient samples to process the last sub-block. Because the sample order is reversed, these extra samples generally occur before the start of the conventional positive transition.

Each sub-block sample 1314 generally begins at the index SSAMP and ends at index ESAMP. For the first sub-block to be processed, SSAMP may be set to 1 and ESAMP may be set to TSPAN. Process block 1316 may be repeated while SSAMP is less than the number of samples in the transition block. For the last sub-block processed, ESAMP will usually be equal or greater than the number of samples in the transition data block.

The variable MINLENG, e.g., minimum value of the measure of length, may be initialized to a value that is greater than any possible calculated value.

Another process block 1318 may be repeated for each value of j in the range of 1 to TSHIFT, where j is used as an offset in the samples in TEMPLATE[ ] relative to the samples in BUFFER[ ]. In the example, only the power samples are processed by this process block 1318.

The variable TLENG may be used to calculate the measure of length. The variable may be initialized to 0. Another process block 1320 may be repeated for each value of k in the range of SSAMP to ESAMP. In the process block 1320, TEMP1 represents the value of the raw data minus the template value shifted by j samples. TEMP2 represents the next value of the raw data minus the next template value. In the example, the incremental length of TLENG is the square root of 1 plus the square of the difference between TEMP1 and TEMP2, e.g., the measure of length. In the example, TLENG accumulates the incremental length for each sample pair.

After TLENG is calculated, it may be compared to the current value of MINLENG, as indicated by 1322. If less, then MINLENG may be set equal to TLENG and the value of the shift variable j may be saved in MSHIFT, as indicated by 1324.

After the process bock 1316 completes, MSHIFT represents the value of the shift parameter j that produced the smallest value for the measure of length within the sub-block. Another process block 1326 may be used to calculate the sample values for power, reactive power, and current within the range of the sub-block. These values may be stored in WORKING[ ], and the value of MSHIFT is the same for each parameter. In the example, this completes the process block 1316 for the sub-block.

In the example, the value of SSAMP for the next sub-block is ESAMP+1 of the sub-block just processed, where the value of ESAMP of the next sub-block is SSAMP of the next sub-block plus TSPAN. The process block 1316 may be repeated until all of the sub-blocks in the transition data block are processed.

After the process block 1316 completes processing of all of the sub-blocks, the two samples before and two samples after each sub-block boundary may be adjusted to smooth the boundary, as indicated by 1328. The smoothing process may use the fast filter function described above for the CHAOTIC REMOVAL process 1100. The temporary value of each of these four samples represents the average of the two adjacent samples. The original values may be replaced by the temporary values, and the process may be repeated. Two iterations generally produce sufficient smoothing.

The template values may be biased so that their values average to zero. The MASKING REMOVAL 616 used before and after bias the removal to the long term minimum of the masking data cycles. This difference in offset may be corrected by adding the minimum sample value in TEMPLATE[ ], a negative value, to each sample in WORKING[ ].

The processed values in WORKING[ ] within the transition data block may then be copied, e.g., in reverse order, into the RAW DATA BUFFER 1 604. This typically completes the PERIODIC REMOVAL process 1300.

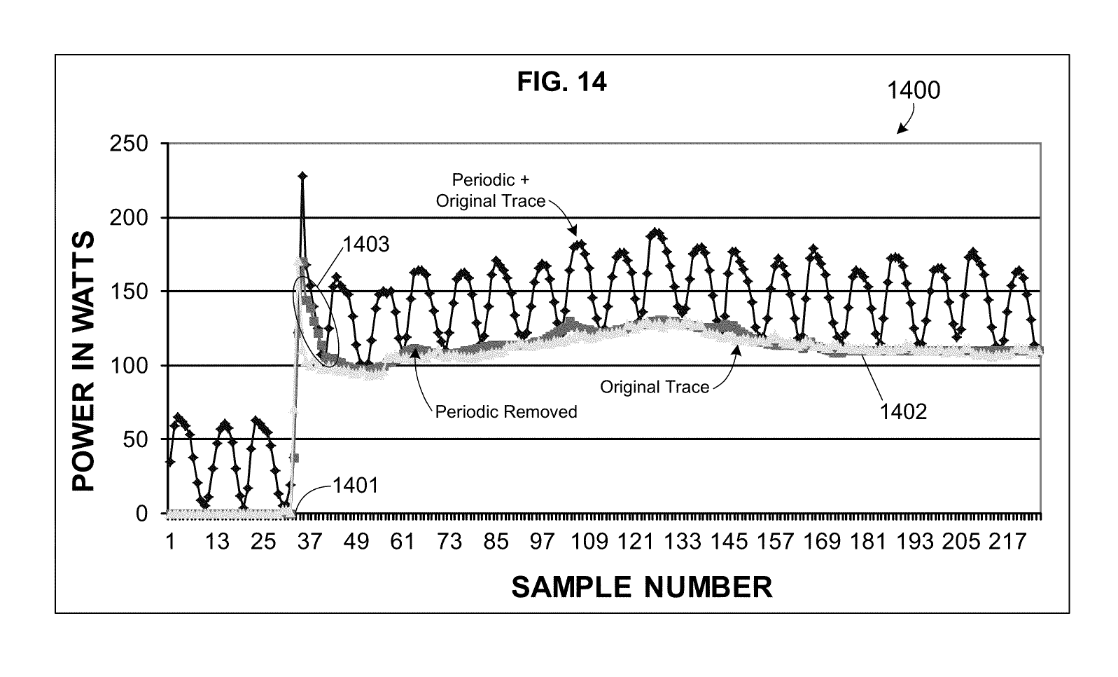

FIG. 14 is an overlay graph 1400 of power samples illustrating typical results of the PERIODIC REMOVAL process 1300 of FIG. 13, in accordance with certain embodiments of the disclosed technology. The graph 1400 shows a combination of periodic data and a conventional positive transition, the positive transition after processing by the PERIODIC REMOVAL process 1300, and the expected original positive transition.

A first trace in the graph 1400 represents the combination of the masking data and the conventional positive transition. In the example, the shape of the transition is obscured. Here, the TRANSITION DETECTOR 614 has detected a fast positive transition at sample 1401. The masking data cycles in the transition data block span from three samples before sample 1401 to sample 1402.

A second trace in the graph 1400 represents the result of processing by the MASKING REMOVAL 616 and the PERIODIC REMOVAL process 1300. In the example, the samples in the transition block have been processed by the PERIODIC REMOVAL process 1300, whereas the samples before and after the transition block have been processed by the MASKING REMOVAL 616. The samples after 1402 show small step changes at the boundary of power cycles that cause MINPV to change.

A third trace in the graph 1400 represents the expected conventional positive transition. The features of the second and third traces are sufficiently similar that the conventional time trace disaggregation process may associate the conventional positive transitions to the same device. The major differences in the example occur for the samples within ellipse 1403. However, these differences are not significant to the time trace disaggregation process.

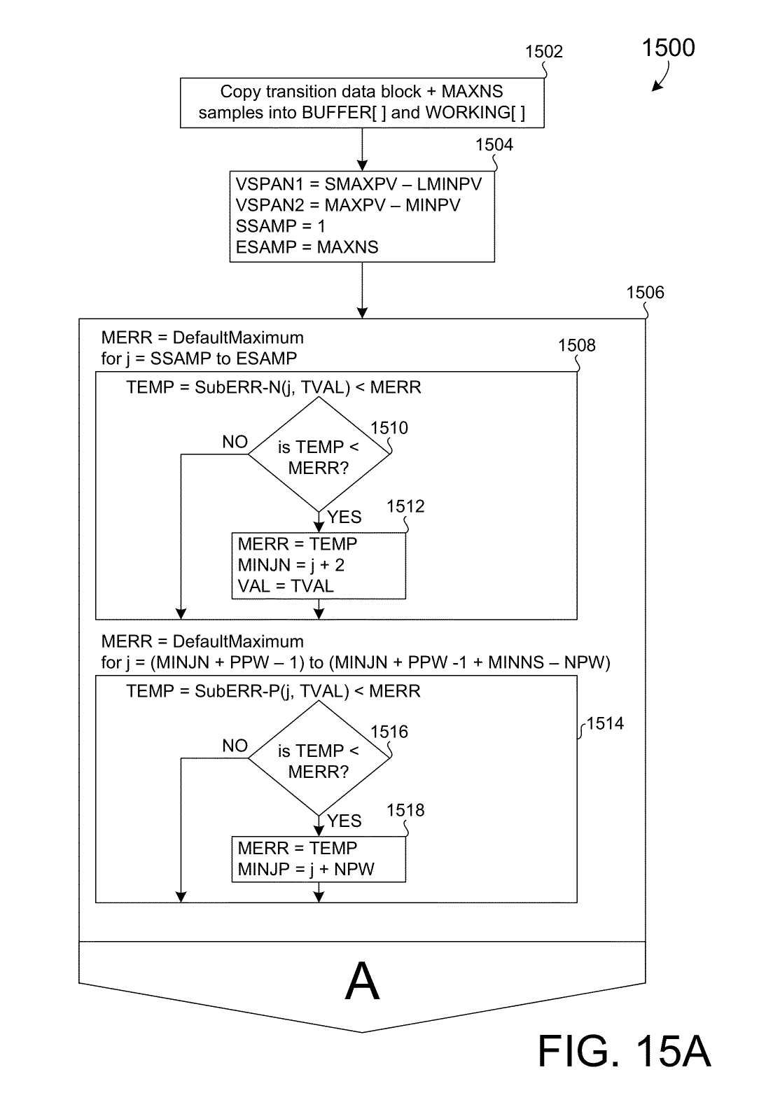

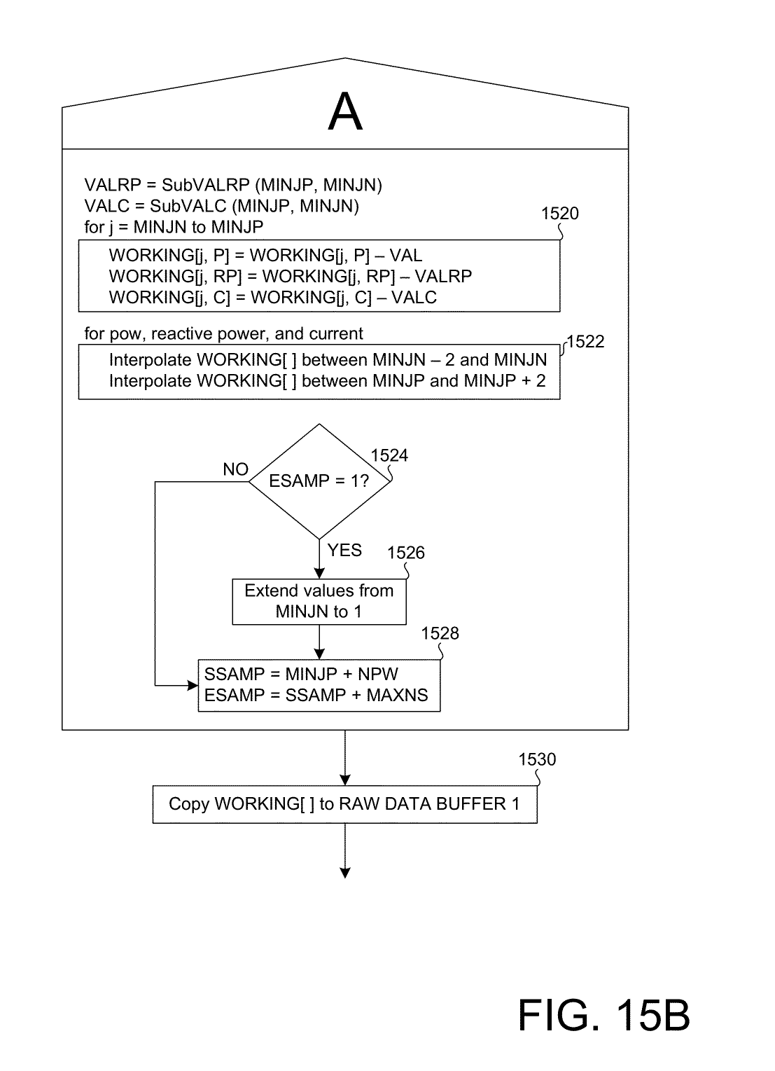

FIGS. 15A and 15B together constitute a flow diagram of a RECTANGULAR REMOVAL process 1500, such as may be called by the CYCLE CHARACTERIZATION 612 of FIG. 6, in accordance with certain embodiments of the disclosed technology. In the example, the process 1500 is an iterative process that removes one masking data cycle for each iteration step. The process 1500 generally begins at the end of the transition data block where the values tend to be most stable. This typically makes synchronization of the removal process with the masking data easier and more accurate than if processing started at the beginning

The transition data block plus MAXNS more samples may be copied into BUFFER[ ] and WORKING[ ], as indicated by 1502. The extra samples may ensure that there are sufficient samples to complete the last iteration cycle. The data may be stored in reverse order so that the oldest sample is at the first index. In the example, the arrays BUFFER[ ] and WORKING[ ] have two dimensions to store power, reactive power, and current values for each sample.

In the example the positive and negative transitions in the masking data are fully complete within two samples. There are NPW>=2 samples near minimum value PPW>=2 samples near maximum value.

The global variable VSPAN1 represents the minimum possible value of the masking data after a positive transition, and the global variable VSPAN2 represents the maximum possible value of the masking data after a positive transition. The values for VSPAN1 and VSPAN2, as well as SSAMP and ESAMP, may be established before the main iteration process block 1506, as indicated by 1504.

During the main iteration process block 1506, SSAMP represents the first sample of the sub-bock and ESAMP represents the last sample of the sub-block. Here, the span of the sub-block is the MAXNS, e.g., maximum number of samples, of a masking data cycle. The start of the sub-block may be advanced each iteration cycle until SSAMP exceeds the number of samples in the transition data block, for example.

The variable MERR may used to store the minimum error found during the process block 1508. MERR may be set to a very large value before the start of process block 1508, e.g., to ensure that it will be replaced during the first iteration.

In the example, process block 1508 may process samples from the end of the transition data block, e.g., largest sample number and smallest index value, toward the start of the block. The processing may find the index of the negative transition of the masking data. A variable j may be used to index samples. A function SubERR-N(j, TVAL) assumes that there is a masking data negative transition at or between samples j (about equal to MINPV) and j+3 (about equal to MAXPV). The function then determines the best removal possible using values between VSPAN1 and VSPAN2. The return value represents a measure of the error after removal, and TVAL is the value between VSPAN1 and VSPAN2 that produces the smallest error.

The error value TEMP returned by SubERR-N may be compared to MERR, as indicated by 1510. If TEMP is less then MERR, then MERR may set to TEMP, as indicated by 1512. Additionally, the variable MINJN may be set to the index of the first stable value before the negative transition and the variable VAL may be set to the value between VSPAN1 and VSPAN2 that produced this smaller error value, also as indicated by 1512.

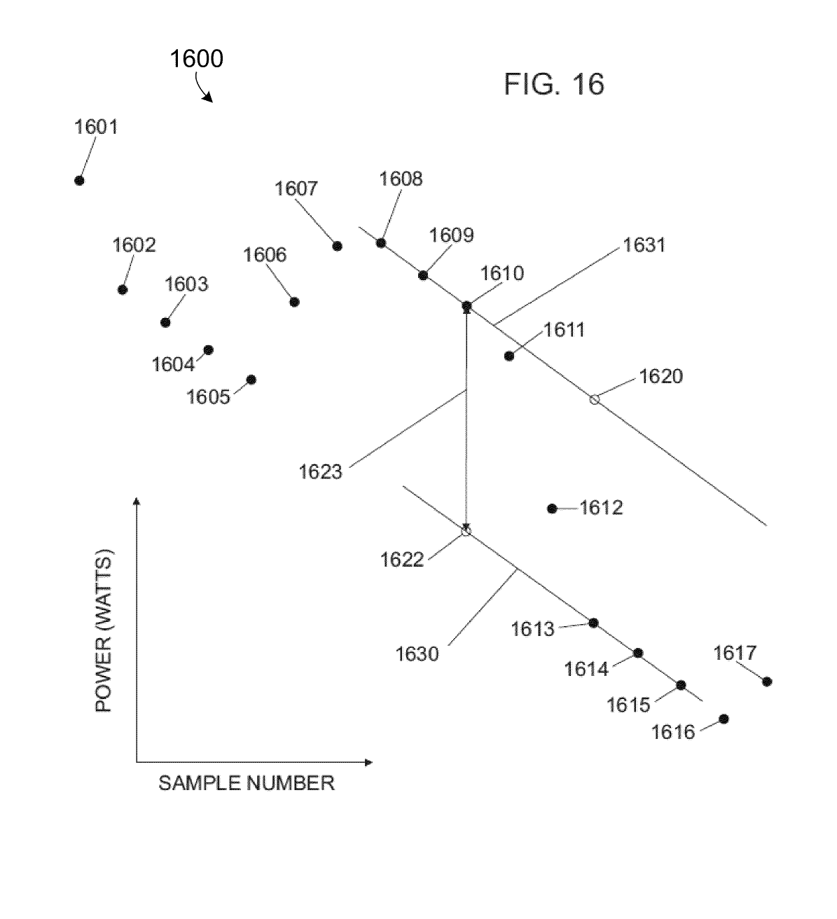

FIG. 16 is a graph 1600 of decreasing power samples of a conventional positive transition with a cycle of rectangular type masking data in accordance with certain embodiments of the disclosed technology. The process used by function SubERR-N, described above, will be further described by way of this example. In the graph 1600, the samples are graphed in their natural order. Since the data is copied into BUFFER[ ] in reverse order in this example, increasing values of j are indexed to decreasing sample numbers. Therefore, the function SubERR-N processes samples from right to left. In the example, samples 1602 through 1605 and samples 1613 through 1616 are not affected by the masking data. Samples 1601, 1606 through 1612, and 1617 are affected by the masking data. Samples 1606, 1607, 1611, and 1612 are samples affected by the positive and negative transitions of the masking data cycle. Samples 1608 through 1610 are offset by 1623, which represents the maximum value of the masking data. This offset is typically between VSPAN1 and VSPAN2. For this example, PPW=3 samples and NPW=4.

Consider an example in which the value of j indexes sample 1613. If NPW=2, then samples 1613 and 1614 may be fit to a linear equation. If NPW>=3, samples 1613, 1614, and 1615 may be fit to a quadratic equation. The equation may be used to generate line 1630 and predict the value of sample 1610. For this example, the predicted value is represented by 1622. If PPW=2, samples 1609 and 1610 may be fit to a linear equation. If PPW is >=3, the samples 1608, 1609, and 1610 may be fit to a quadratic equation. The equation may be used to generate line 1631 and predict the value of sample 1613. For this example, the predicted value is represented by 1620. The RMS error of these two predictions is generally the square root of the sum of the squares of the differences between sample pair 1610 and 1622 and between sample pair 1620 and 1613. The offset 1623 is typically restricted to values in the range of VSPAN1 to VSPAN2. The value in this range that produced the smallest RMS error is generally the value of the returned variable TVAL. The value of the smallest RMS error is generally the return value of the function SubERR-N.

Some rectangular masking data have transitions that occur between samples or within one sample. For example, sample 1611 could be on line 1631 and sample 1612 could be on line 1630. For this example, there will be three values of j with nearly identical RMS error. However, the removal process would produce nearly identical results for any of the three values of j.

Returning to FIG. 15, the process block 1514 may be used to find the masking data positive transition associated with the negative transition found in process block 1508. In the example, the search begins at index MINJN (the first stable value before the negative transition)+PPW−1. Here, the positive transition can not occur before this sample. The search may then continue for MINNS−NPW samples, and the positive transition is certain to be within this range. The variable MERR may be set to a large value, and the function SubERR-P may return the RMS error of predicted sample values using VAL as the offset. This process is similar to that of SubERR-N described above except that the offset value here is fixed to be equal to VAL. The process 1514 assumes j to be the index to the first stable value after the positive transition, see, e.g., sample 1608 in the graph 1600 of FIG. 16.

For each j in the range (MINJN+PPW−1) to (MINJN+PPW−1+MINNS−NPW), TEMP may be set to the return value of SubERR-P. TEMP may be compared to MERR, as indicated by 1516. If TEMP is less than MERR, then MERR may be set to TEMP and MINJP may be set to the first stable value after the positive masking data transition, as indicated by 1518.

After the process block 1514 completes, the portion of the masking data cycle that is stable and has near maximum value includes the samples beginning with MINJP and ending with MINJN. These values may be passed to functions SubVALRP and SubVALC, which respectively process the reactive power data samples and current data samples in WORKING[ ]. The value of the offset of the samples in the specified range may be selected to minimize the RMS error of the predicted values before the positive transition and after the negative transition, see, e.g., the SubERR-N function described above. The variable VALRP may be set to the return value from the function SubVALRP, and the variable VALC may be set to the return value from the function SumValC.

A process block 1520 may process each sample in the range of MINJN to MINJP. In the example, the values VAL, VALRP, and VALC may be subtracted from the power, reactive power, and current samples in WORKING[ ].

Another process block 1522 may be used to calculate the values of the two samples before and after the stable range MINJN to MINJP. These values for power, reactive power, and current may be determined using liner interpolation of the sample values on either side of sample pairs.

In certain embodiments, the masking data may be maximum when ESAMP=1. Because process block 1508 searches for the first negative transition, some samples in the range of MINJN to 1 may have the masking data removed. In these embodiments, a determination may be made as to whether ESAMP=1, as indicated by 1524. When ESAMP=1, the values may be extended from MINJN to 1, as indicated by 1526. That is, the sample value at index MINJN may be copied to all samples from MINJN−1 to 1. This may be done for power, reactive power, and current.

After completion of the main process block 1506, WORKING[ ] typically contains the sample values with the masking data removed. The sample values for power, reactive power, and current may be copied from WORKING[ ] to RAW DATA BUFFER 1 604 for the samples in the range of the transition data block, as indicated by 1530. This typically completes the RECTANGULAR REMOVAL process 1500.

The PULSE REMOVAL process generally removes a pulse by identifying the sample just before the pulse and the sample just after the pulse. There are typically one to four samples affected by the pulse between the before and after samples. In most cases, the in-between samples may be replaced with sample values that are linearly interpolated using the before and after samples. If the pulse is coincident with a step or peak of the conventional positive transition, then the effects of the pulse may be removed in a way that preserves the step or peak feature.

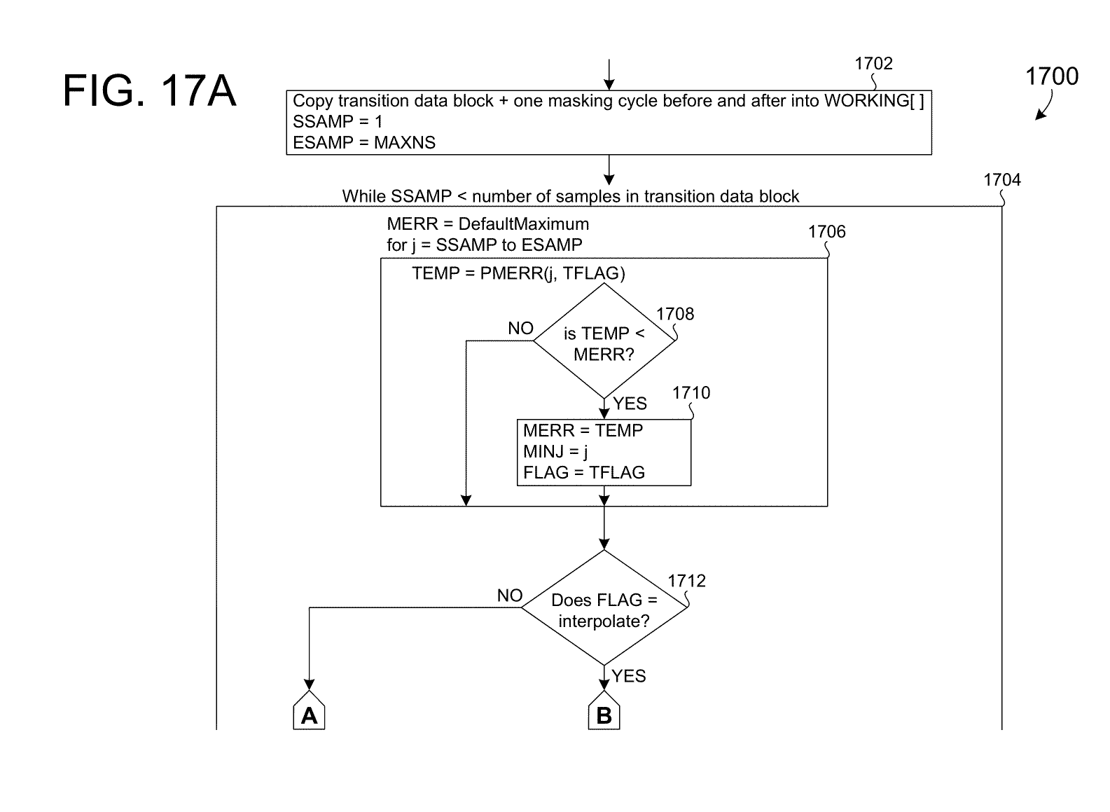

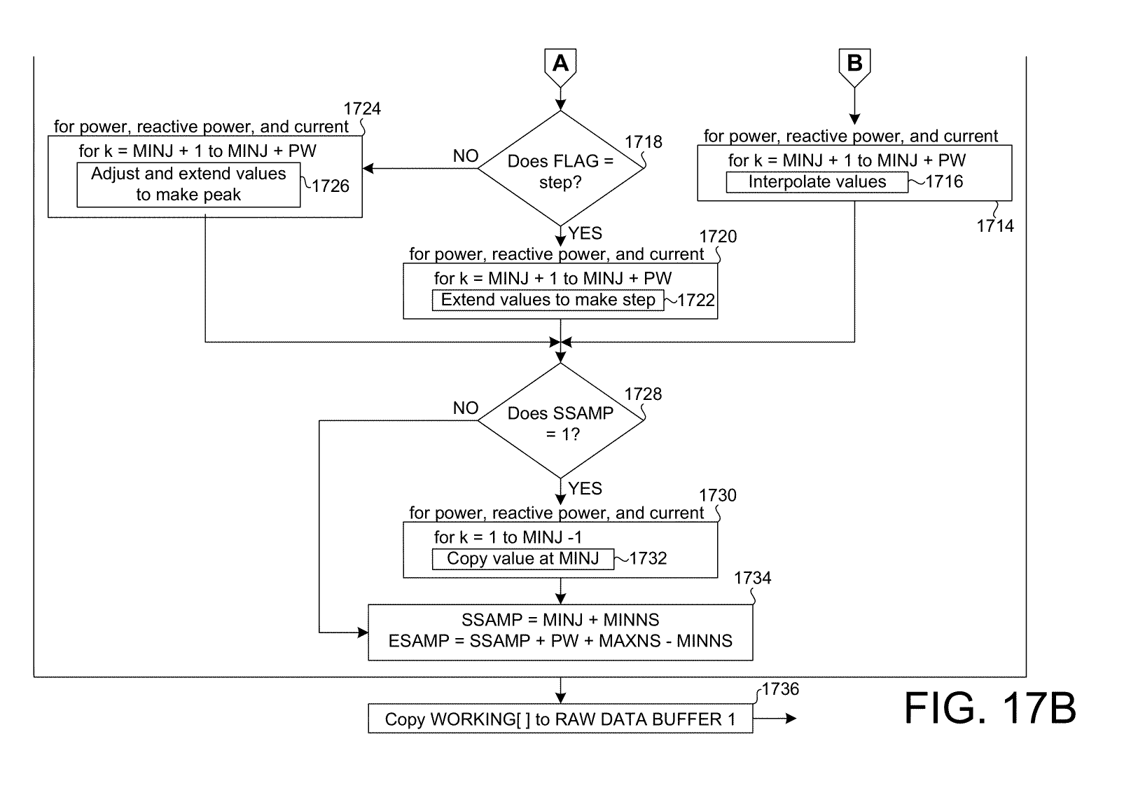

FIGS. 17A and 17B together constitute a flow diagram of a PULSE REMOVAL process 1700, such as may be called by the CYCLE CHARACTERIZATION 612 of FIG. 6, in accordance with certain embodiments of the disclosed technology. This process 1700 is typically an iterative process, where each iteration removes one pulse. The process 1700 generally works in reverse order as does the RECTANGULAR REMOVAL process 1500 described above.

There are generally two versions of this process 1700. The version now described is for the more common positive PULSE type masking data. Those ordinarily skilled in the art can readily adapt the following description for removing negative PULSE type masking data.

The transition data block plus MAXNS more samples may be copied into WORKING[ ], as indicated by 1704. The extra samples generally ensure there are sufficient samples to complete removal of the last iteration cycle. The data may be stored in reverse order so that the oldest sample is at the first index. In the example, WORKING[ ] has two dimensions to store power, reactive power, and current values for each sample.

In the example, the sample at index SSAMP=1 represents the first sample of the first sub-block processed, and the sample at index ESAMP=MAXNS represents the last sample of the first sub-block processed. SSAMP and ESAMP may be set before the main process block 1704, as also indicated by 1702.

In the example, the main process block 1704 iterates until SSAMP is greater than the number of samples in the transition data block.

A process block 1706 the samples in the sub-block for the most likely position of a masking data pulse. The samples affected by the pulse are MAXNS−NPW. A function PMERR may be used to return a match error between a masking data pulse PW samples wide. Here, the index j is assumed to be the first stable value after the pulse negative transition.

A variable MEER may be set to a large value that is greater than any return value from PMEER. For each sample in the sub-block, TEMP may set to the error value for the sample. TEMP may then be compared to MEER, as indicated by 1708. If TEMP is less than MEER, then MERR may be set to TEMP, MINJ may be set to the sample index, and FLAG may be set to the value of TFLAG returned by PMERR, as indicated by 1710.

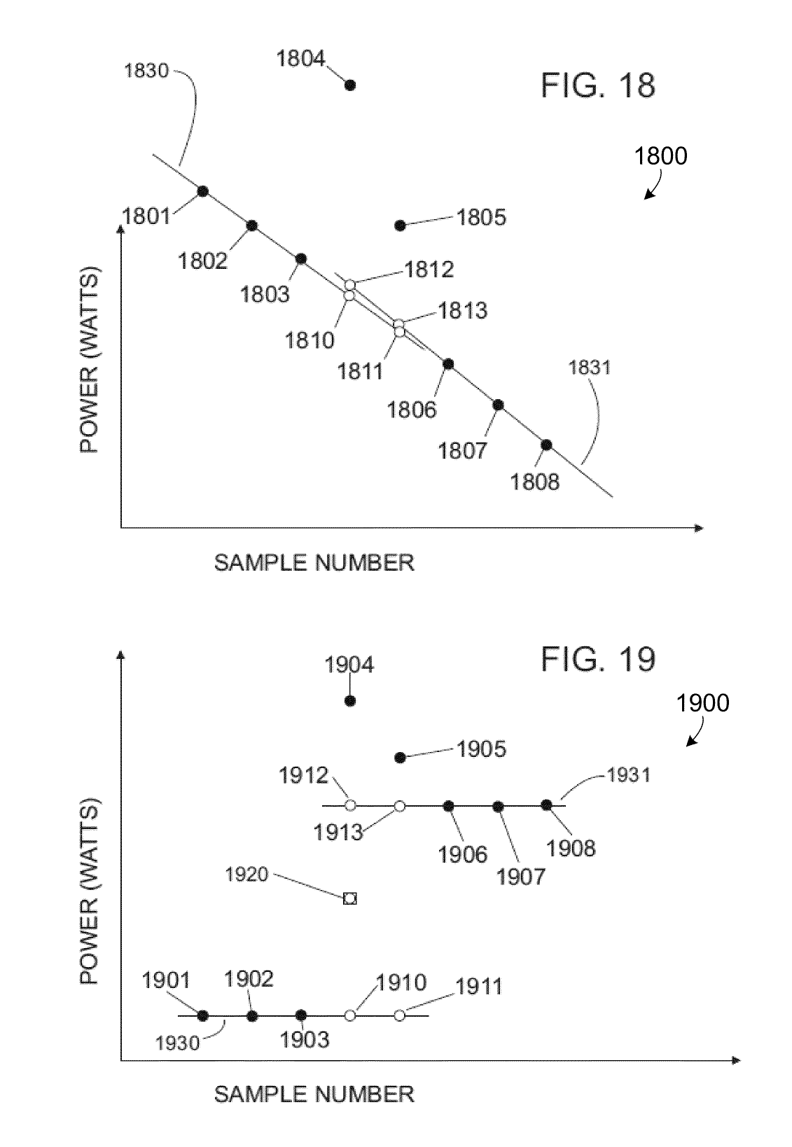

FIG. 18 is a graph 1800 of the power samples of a decreasing portion of a conventional positive transition combined with one pulse masking data cycle in accordance with certain embodiments of the disclosed technology. In the example, samples 1804 and 1805 are affected by the positive pulse cycle.

Consider an example in which PW=2 and the value of j indexes the sample 1806. If NPW is =>3, then PMERR may use samples 1806, 1807, and 1808 and the least squares linear fit process to determine the equation of line 1831. This process may also produce a number DEV1 representing the deviations of the sample values from the values predicted by the equation. This process may be repeated using the samples 1801, 1802, and 1803 to determine the equation of line 1830 and the deviation DEV2. In the example, the deviations each represent a measure of the error from using the equations to represent the values.

If NPW=2, then PMERR may use samples 1806 and 1807 to determine line 1831 and samples 1802 and 1803 to determine line 1830. The deviations DEV1 and DEV2 may be set to zero.

These two equations may be used separately to predict the values of samples 1804 and 1805. These values may be represented by samples 1810 and 1811, respectively, for line 1830. The values predicted by line 1831 may be represented by 1812 and 1813. Here, the difference between sample 1804 and the larger of the two predicted values (1812) is the contribution from the pulse. Similarly, the difference between sample 1805 and the larger of the two predicted values (1813) is also the contribution from the pulse. The maximum of these two differences should be between MINPUL=SMAXPV−LMINPV (minimum pulse value) and MAXPUL=MAXPV−MINPV (maximum pulse value). EXERR represents the error of this comparison. If the maximum difference is within the range MINPUL to MAXPUL, there is no error and EXERR=0. If not in the range, EXERR=the magnitude of the excess or shortfall.

The error values DEV1, DEV2, and EXERR may be normalized using MAXPUL and combined to make a single RMS error value that has minimum value when j is the index to the first sample after the pulse that is not affected by the pulse. The combined and normalized error value may be returned by PEMERR.

PEMERR may also return a parameter TFLAG that specifies one of three processes for replacing the samples affected by the masking pulse. FIG. 18 illustrates a portion of the conventional positive transition that is stable or changing at a relatively stable rate. In the example, the slope of line 1830 is about the same as the slope of line 1831. Additionally, the differences between the predicted values 1810 and 1812 for sample 1804 and predicted values 1811 and 1813 for sample 1805 are small compared to MAXPUL. For this case, the process for replacing values affected by the masking pulse is a linear interpolation between sample 1803 and sample 1806. TFLAG may be returned set to a value specifying the interpolation.

FIG. 19 is a graph 1900 of the power samples of a step portion of a conventional positive transition combined with one pulse masking data cycle in accordance with certain embodiments of the disclosed technology. This could represent the start of the transition, or a secondary transition following the initial transition. The slopes of lines 1930 and 1931 in the graph 1900 are about the same, but the differences between predicted values 1910 and 1912 and values 1911 and 1913 are significant. For this case, TFLAG may be returned set to a value specifying the step. Here, the process for replacing 1904 would be to use line 1930 to predict its value and the process for replacing sample 1905 would be to use line 1931 to predict its value.

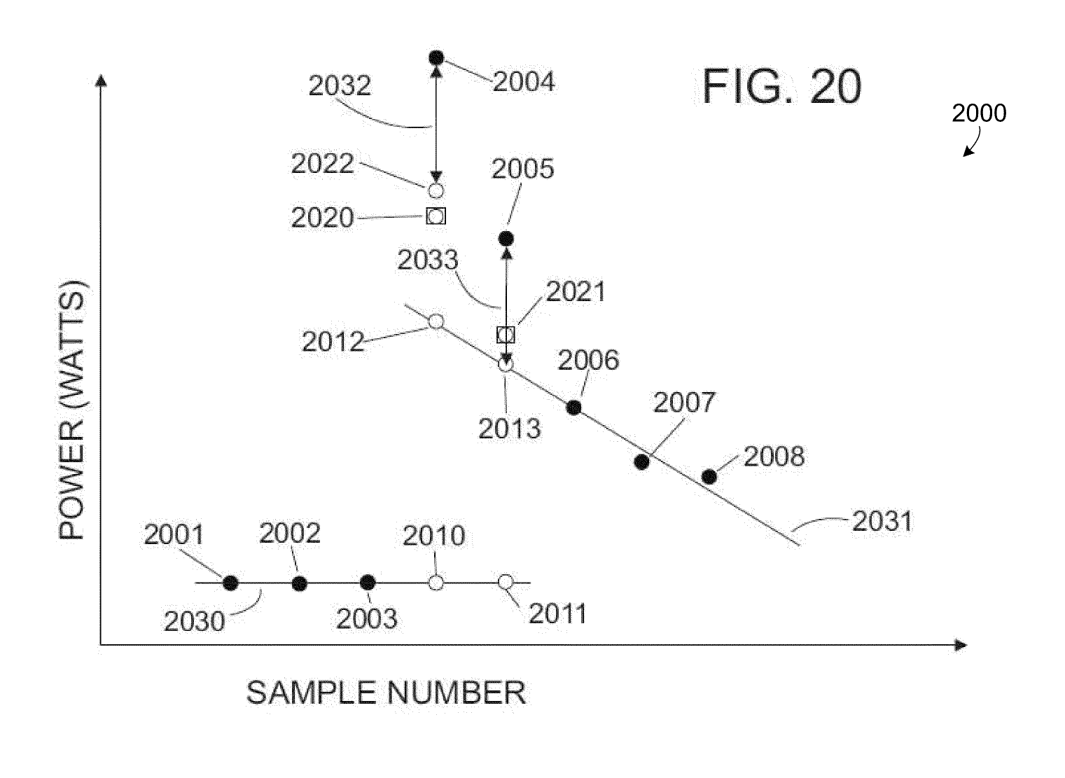

FIG. 20 is a graph of the power samples of a peak portion of a conventional positive transition combined with one pulse masking data cycle in accordance with certain embodiments of the disclosed technology. This could represent the start of the transition, or a secondary transition following the initial transition. The slopes of lines 2030 and 2031 in the graph 2000 are significantly different, and the predicted values for samples 2004 and 2005 are significantly different. For this case, TFLAG may be returned set to a value specifying the peak.

After the process block 1706 of FIG. 17 completes, MINJ represents the index to the first unaffected sample after the masking pulse and FLAG specifies the process for removing the effects of the pulse. In the example, samples with index MINJ+1 to index MINJ+PW will be replaced.

A determination is made as to whether the value of FLAG represents interpolation, as indicated by 1712. If the value of FLAG represents interpolation, a process block 1714 may operate on the samples in WORKING[ ] for power, reactive power, and current. Here, the index for the before value is MINJ+PW+1 and the index for the after value is MINI A process block 1716 replaces the values of the affected samples between the before and after samples. The values between are on the straight line connecting the before and after values.

If the value of FLAG does not represent interpolation, a subsequent determination is made as to whether the value of FLAG represents step, as indicated by 1718.

If the value of FLAG represents step, a process block 1720 may operate on the samples in WORKING[ ] for power, reactive power, and current. Another process block 1722 may replace samples with index nearest MINJ with the value at index MINI Samples with index nearest MINJ+PW may be replaced with the value at index MINJ+PW. Samples with index MINJ+1 to index MINJ+PW may be replaced.

If the value of FLAG is not interpolation and not step, another process 1724 may operate on the samples in WORKING[ ] for power, reactive power, and current. This process block 1724 may replace samples with index MINJ+1 to index MINJ+PW. This process may serve to preserve the peak feature shape. The conventional disaggregation process recognizes the peak feature when the samples increase in a step followed by a rapid decrease. The actual value of the peak maximum is not necessarily important.

Using FIG. 20 as an example, the unaffected value of samples 2004 and 2005 in the graph 2000 are represented by 2020 and 2021. The value of samples 2004 and 2005 predicted by line 2031 are represented by 2012 and 2013. In the example, line 2032 represents the average value of MINPUL and MAXPUL. This is subtracted from the value of sample 2004 to produce the replacement value represented by 2022.

If the difference between sample 2005 and the predicted value 2013 is less than the average masking pulse value represented by line 2033, then the replacement value is the predicted value 2013. If the difference between sample 2005 and the predicted value 2013 is greater than the average masking pulse value, then the average is subtracted from 2005 to produce the replacement value. In this example, the replacement value is the predicted value.

In certain embodiments, the pulse masking data may be maximum when ESAMP=1. Because process block 1706 searches for the first negative transition, some samples in the range of MINJ to 1 may have masking data that is not replaced. A determination may be made as to whether ESAMP=1, as indicated by 1728. If ESAMP=1, then a process block 1730 may operate on the samples in WORKING[ ] for power, reactive power, and current. Another process block 1732 may copy the sample value at index MINJ to all indexes from MINJ−1 to 1.

After the samples affected by the masking pulse are replaced, the sample range for the next iteration may be set, as indicated by 1734. The next pulse negative transition will be at least MINNS samples before MINJ. Therefore, SSAMP may be set to MINJ+MINNS. In the example, the next pulse positive transition will be no more than PW+MAXNS−MINNS samples before the new value of SSAMP. ESAMP may be set to SSAMP+PW+MAXNS−MINNS. This range ensures that, in the next iteration, the function PMERR will be called for indexes before and after the index of the negative transition.

After the main process block 1704 completes, the samples in the transition data block in WORKING[ ] may be copied to RAW DATA BUFFER 1 604, as indicated by 1736.

Having described and illustrated the principles of the invention with reference to illustrated embodiments, it will be recognized that the illustrated embodiments may be modified in arrangement and detail without departing from such principles, and may be combined in any desired manner. And although the foregoing discussion has focused on particular embodiments, other configurations are contemplated. In particular, even though expressions such as “according to an embodiment of the invention” or the like are used herein, these phrases are meant to generally reference embodiment possibilities, and are not intended to limit the invention to particular embodiment configurations. As used herein, these terms may reference the same or different embodiments that are combinable into other embodiments.

Consequently, in view of the wide variety of permutations to the embodiments described herein, this detailed description and accompanying material is intended to be illustrative only, and should not be taken as limiting the scope of the invention. What is claimed as the invention, therefore, is all such modifications as may come within the scope and spirit of the following claims and equivalents thereto.

What is claimed is:

1. A method comprising:
receiving raw data from a monitor, said raw data comprising a plurality of power samples corresponding to at least one electrical device;
a cycle detector processing each of the plurality of power samples to detect at least one masking data cycle;
the cycle detector determining a plurality of masking parameters that characterize the at least one masking data cycle;
storing the plurality of power samples in at least one circular data buffer;
storing the plurality of masking parameters in a circular cycle parameter buffer; and
a cycle characterization determining whether there is masking data within the raw data.

2. The method of claim 1, wherein detecting the masking data cycle comprises the cycle detector determining that a significant maximum one of the plurality of power samples followed by a minimum one of the plurality of power samples occurs within a particular span of the plurality of power samples.

3. The method of claim 2, wherein the particular span of the plurality of power samples is 70 samples.

4. The method of claim 2, wherein each of the plurality of power samples spans approximately one second.

5. The method of claim 1, wherein determining whether there is masking data within the raw data comprises the cycle characterization determining whether there are a particular number of consecutive masking data cycles that span less than a particular number of the plurality of power samples.

6. The method of claim 5, wherein the particular number of consecutive masking data cycles is four.

7. The method of claim 1, further comprising the cycle characterization tracking long-term maximum and minimum values of power, reactive power, and current in the raw data while the masking data is present within the raw data.

8. The method of claim 7, further comprising the cycle characterization determining the maximum and minimum values by processing the plurality of masking parameters.

9. The method of claim 7, further comprising replacing the values of power, reactive power, and current in the raw data with the long-term minimum values tracked by the cycle characterization.

10. The method of claim 1, further comprising a clip removal removing the masking data from the raw data.

11. The method of claim 1, further comprising:
a transition detector detecting at least one transition within the plurality of power samples associated with at least one type of conventional device; and
the cycle detector ignoring at least one transition caused by the masking data.

12. The method of claim 10, further comprising:
the cycle characterization determining that there is masking data within the raw data; and
a transition detector detecting a negative transition within the plurality of power samples associated with a conventional device.

13. The method of claim 12, further comprising the clip removal determining a most probable one of the plurality of power samples within the masking data cycle when the negative transition occurs.

14. The method of claim 13, further comprising:
the cycle characterization tracking long-term minimum values of power, reactive power, and current in the raw data while the masking data is present within the raw data; and
replacing at least some of the plurality of power samples before the most probable one of the plurality of power samples with at least one of the long-term minimum values tracked by the cycle characterization.

15. The method of claim 14, further comprising the clip removal using data in the cycle parameter buffer for at least one masking data cycle after the negative transition.

16. The method of claim 1, further comprising a transition detector detecting at least one transition associated with at least one type of conventional device.

17. The method of claim 16, wherein the at least transition may be recognized and processed by a time trace disaggregation process.

18. The method of claim 16, wherein the at least one transition comprises at least one negative transition, at least one positive transition, or at least one negative transition and at least one positive transition.

19. The method of claim 1, further comprising the cycle characterization calling a removal process to remove masking data from the raw data.

20. The method of claim 19, wherein the removal process comprises one of a group consisting of:
a chaotic removal process;
a periodic removal process;
a rectangular removal process; and
a pulse removal process.

21. A filter mechanism system for use with time trace disaggregation, the filter mechanism comprising:
a masking data detector configured to detect masking data within raw data received from a power sample monitor; and
a preprocessor configured to selectively apply at least one of a plurality of filter processes to remove detected masking data.

22. The filter mechanism system of claim 21, wherein said plurality of filter processes comprises:
a chaotic removal process,
a periodic removal process,
a rectangular removal process, and
a pulse removal process.

23. The filter mechanism system of claim 21, said plurality of filter processes further comprising a clip removal process.

24. The filter mechanism system of claim 21, further comprising a masking characterization configured to characterize the masking data, wherein said preprocessor is further configured to select a filter process that best removes said detected masking data based on said characterizing of the masking data.

25. The filter mechanism system of claim 21, further comprising a transition detection process for detecting within the raw data transitions of a normal device when said masking data is present.

26. The filter mechanism system of claim 25, wherein said preprocessor selectively applies at least one of the plurality of filter processes while said normal transitions are active.

27. The filter mechanism system of claim 25, wherein said plurality of filter processes further comprises a clip removal process, and wherein said preprocessor uses said clip removal process when no normal transitions are active.

28. The filter mechanism system of claim 21, further comprising a masking device manager configured to capture the masking data as instances and devices and associate energy use with those instances and devices.

29. The filter mechanism system of claim 28, further comprising an instance storage configured to store said instance masking data.

30. The filter mechanism system of claim 28, further comprising a device storage configured to store said device masking data.
